(19) United States
(12) Patent Application Publication
(10) Pub. No.: US 2026/0090117 A1
(43) Pub. Date: Mar. 26, 2026

(54) IMAGING DEVICE AND ELECTRONIC APPARATUS

(71) Applicant: SONY SEMICONDUCTOR SOLUTIONS CORPORATION, Kanagawa (JP)

(72) Inventor: Yu SHIIHARA, Kanagawa (JP)

(73) Assignee: SONY SEMICONDUCTOR SOLUTIONS CORPORATION, Kanagawa (JP)

(21) Appl. No.: 19/108,834

(22) PCT Filed: Aug. 16, 2023
(86) PCT No.: PCT/JP2023/029558

§ 371 Date: Mar. 5, 2025

(30) Foreign Application Priority Data
Sep. 15, 2022 (JP) 2022-147342

(51) Int. Cl. H10F 39/00; H10F 39/18

(52) U.S. Cl. CPC H10F 39/8057; H10F 39/182; H10F 39/8053; H10F 39/8063

(57) ABSTRACT

An imaging device with a semiconductor substrate, a photoelectric converter, an electric charge holder, and a first light-blocking section. The semiconductor substrate includes a pixel array section of unit pixels. The first light-blocking section includes a first horizontal light-blocking part and a first vertical light-blocking part that is orthogonal to the first horizontal light-blocking part. The first vertical light-blocking part includes a first row light-blocking part and a first column light-blocking part. The first vertical light-blocking part is provided for each of the unit pixels positioned every other column and in a 45-degree oblique direction. The first horizontal light-blocking part has, in plan view, an end at or in the vicinity of a position connecting one and another of intersections of the first row light-blocking parts and the first column light-blocking parts that are provided for the respective unit pixels positioned every other column and in the 45-degree oblique direction.

### TECHNICAL FIELD

The present disclosure relates to an imaging device and an electronic apparatus that each perform imaging by performing photoelectric conversion.

### BACKGROUND ART

For example, regarding an imaging device in which a photoelectric converter is provided on light irradiation surface side of a Si{111} substrate, and an electric charge holder is provided on a surface on opposite side to a light irradiation surface, PTL 1 proposes to improve light-blocking performance for the electric charge holder by forming a space in a horizontal direction of the substrate from a trench end, with use of crystal orientation anisotropy of alkaline etching, and providing a horizontal light-blocking part between the photoelectric converter and the electric charge holder.

### CITATION LIST

### Patent Literature

PTL 1: International Publication No. WO2019/240207

### SUMMARY OF THE INVENTION

Incidentally, it is desired to improve an imaging device in electric charge transfer efficiency.

It is therefore desirable to provide an imaging device and an electronic apparatus that each achieve both superior light-blocking performance for an electric charge holder and superior electric charge transfer efficiency.

An imaging device according to one embodiment of the present disclosure includes a semiconductor substrate, a photoelectric converter, an electric charge holder, and a first light-blocking section. The semiconductor substrate includes a first surface and a second surface that are opposed to each other. The semiconductor substrate includes a pixel array section in which multiple unit pixels are arranged in an array in a row direction and a column direction. The photoelectric converter is provided on side of the second surface of the semiconductor substrate for each of the unit pixels, and generates electric charge corresponding to a light reception amount by photoelectric conversion. The electric charge holder is provided on side of the first surface of the semiconductor substrate for each of the unit pixels, and holds the electric charge transferred from the photoelectric converter. The first light-blocking section is provided in the semiconductor substrate and is positioned between the photoelectric converter and the electric charge holder. The first light-blocking section includes a first horizontal light-blocking part and a first vertical light-blocking part. The first horizontal light-blocking part extends in an in-plane direction of the semiconductor substrate. The first vertical light-blocking part is orthogonal to the first horizontal light-blocking part. The first vertical light-blocking part includes a first row light-blocking part and a first column light-blocking part formed along two respective sides, of the unit pixel having a rectangular shape, that are adjacent to each other. The first vertical light-blocking part is provided for each of the unit pixels positioned every other column and in a 45-degree oblique direction. The first horizontal light-blocking part has, in plan view, an end at or in the vicinity of a position connecting one and another of intersections of the first row light-blocking parts and the first column light-blocking parts that are provided for the respective unit pixels positioned every other column and in the 45-degree oblique direction.

An electronic apparatus according to one embodiment of the present disclosure includes the imaging device according to one embodiment of the present disclosure described above.

In each of the imaging device according to one embodiment of the present disclosure and the electronic apparatus according to one embodiment of the present disclosure, a light-blocking section that blocks light between the photoelectric converter and the electric charge holder includes the first vertical light-blocking part and the first horizontal light-blocking part. The first vertical light-blocking part includes the first row light-blocking part and the first column light-blocking part formed along the two respective sides, of the unit pixel having the rectangular shape, that are adjacent to each other. The first vertical light-blocking part is provided for each of the unit pixels positioned every other column and in the 45-degree oblique direction. The first horizontal light-blocking part has, in plan view, the end at or in the vicinity of the position connecting one and another of the intersections of the first row light-blocking parts and the first column light-blocking parts that are provided for the respective unit pixels positioned every other column and in the 45-degree oblique direction. It is thus possible to achieve the light-blocking section having high dimension accuracy.

### BRIEF DESCRIPTION OF DRAWINGS

FIG. 1 is a block diagram illustrating a configuration example of functions of an imaging device according to a first embodiment of the present disclosure.

FIG. 2 is a block diagram illustrating a configuration example of functions of an imaging device as a first modification example of the first embodiment.

FIG. 3 is a block diagram illustrating a configuration example of functions of an imaging device as a second modification example of the first embodiment.

FIG. 4 is a circuit diagram illustrating a circuit configuration of the imaging device illustrated in FIG. 1, etc.

FIG. 5 is a schematic diagram illustrating an example of a plan configuration of the imaging device illustrated in FIG. 1, etc.

FIG. 6 is a schematic diagram illustrating an example of a cross-sectional configuration of the imaging device illustrated in FIG. 5.

FIG. 7A is a schematic plan diagram for describing a method of forming a horizontal light-blocking part illustrated in FIG. 1.

FIG. 7B is a schematic plan diagram illustrating a process following FIG. 7A.

FIG. 8 is a schematic diagram illustrating an example of a layout of color filters.

FIG. 9 is a schematic diagram illustrating an example of a plan configuration of an imaging device according to Modification example 1 of the present disclosure.

FIG. 10 is a schematic diagram illustrating an example of a plan configuration of an imaging device according to a second embodiment of the present disclosure.

FIG. 11 is a schematic diagram illustrating an example of a cross-sectional configuration of the imaging device illustrated in FIG. 10.

FIG. 12 is a schematic diagram illustrating an example of a plan configuration of an imaging device according to a third embodiment of the present disclosure.

FIG. 13 is a schematic diagram illustrating one cross-sectional configuration of the imaging device illustrated in FIG. 12.

FIG. 14 is a schematic diagram illustrating another cross-sectional configuration of the imaging device illustrated in FIG. 12.

FIG. 15 is a schematic diagram illustrating a cross-sectional configuration of an imaging device according to Modification example 2 of the present disclosure.

FIG. 16 is a schematic diagram illustrating an example of a plan configuration according to a fourth embodiment of the present disclosure.

FIG. 17 is a schematic diagram illustrating another example of the plan configuration according to the fourth embodiment of the present disclosure.

FIG. 18 is a schematic diagram illustrating another example of the plan configuration according to the fourth embodiment of the present disclosure.

FIG. 19 is a schematic diagram illustrating an example of a plan configuration of an imaging device according to Modification example 3 of the present disclosure.

FIG. 20 is a diagram for describing a configuration of a vertical light-blocking section illustrated in FIG. 19.

FIG. 21 is a block diagram illustrating an example of a configuration of an electronic apparatus including the imaging device illustrated in FIG. 1.

FIG. 22A is a schematic diagram illustrating an example of an overall configuration of a photodetection system including the imaging device illustrated in FIG. 1, etc.

FIG. 22B is a diagram illustrating an example of a circuit configuration of the photodetection system illustrated in FIG. 22A.

FIG. 23 is a view depicting an example of a schematic configuration of an endoscopic surgery system.

FIG. 24 is a block diagram depicting an example of a functional configuration of a camera head and a camera control unit (CCU).

FIG. 25 is a block diagram depicting an example of schematic configuration of a vehicle control system.

FIG. 26 is a diagram of assistance in explaining an example of installation positions of an outside-vehicle information detecting section and an imaging section.

### MODES FOR CARRYING OUT THE INVENTION

Hereinafter, some embodiments of the present disclosure will be described in detail with reference to the drawings. Described below are specific examples of the present disclosure, and the present disclosure is not limited to the embodiments below. In addition, the present disclosure is not limited to them in terms of arrangements, dimensions, dimension ratios, etc. of components illustrated in each of the drawings. Note that the description will be given in the following order.
1. First Embodiment
(An example of an imaging device including a light-blocking section that includes a vertical light-blocking part having a zigzag shape and an end at a horizontal light-blocking part at a position connecting one and another of intersections of the vertical light-blocking parts
2. Modification Example 1
(An example of the imaging device in which adjacent sensor pixels have a point-symmetric layout)
3. Second Embodiment
(An example of the imaging device including two light-blocking sections extending in an in-plane direction of a semiconductor substrate at respective positions different from each other)
4. Third Embodiment
(Another example of the imaging device including the two light-blocking sections extending in the in-plane direction of the semiconductor substrate at respective positions different from each other)
5. Modification Example 2
(Another example of the imaging device including the two light-blocking sections provided through the semiconductor substrate)
6. Fourth Embodiment
(An example of a layout of the vertical light-blocking part)
7. Modification Example 3
(Another example of the layout of the vertical light-blocking part)
8. Application Examples
9. Practical Application Examples

### 1. First Embodiment

### Overall Configuration of Imaging Device

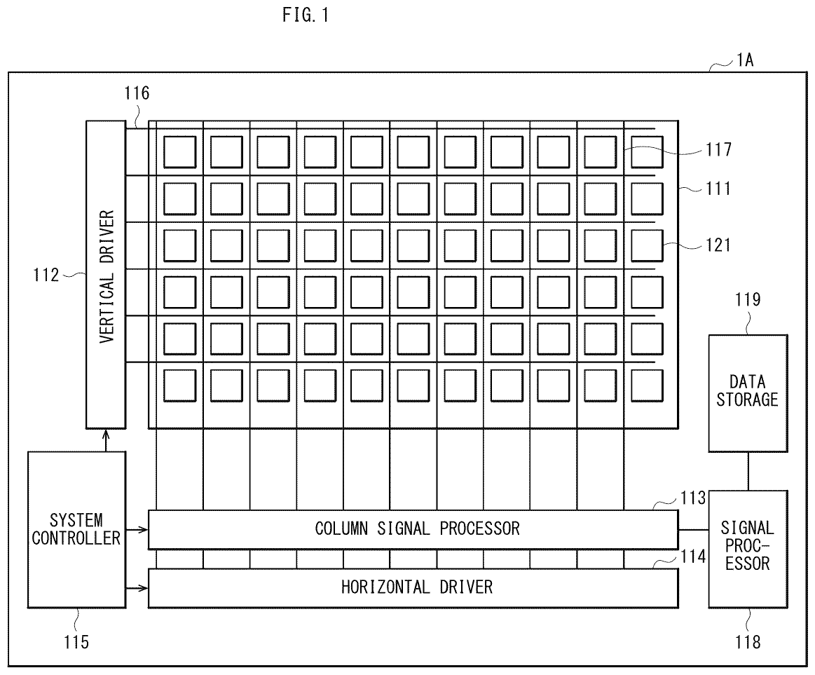

FIG. 1 is a block diagram illustrating a configuration example of functions of an imaging device 1 (an imaging device 1A) according to an embodiment of the present disclosure.

The imaging device 1A is what is called a back-illuminated image sensor of a global shutter method, such as a CMOS (Complementary Metal Oxide Semiconductor) image sensor, for example. The imaging device 1A captures an image by receiving light from a subject, performing photoelectric conversion on the received light, and generating an image signal.

The global shutter method refers to a method of performing a global exposure, in which, basically, an exposure is started for all pixels at the same time and the exposure is ended for all the pixels at the same time. Here, all the pixels refer to all of pixels in a part where an image appears, and excludes a dummy pixel or the like. In addition, if a time difference, image distortion, etc. are small enough not to pose a problem, the global shutter method also encompasses a method of moving a region in which the global exposure is performed, while performing the global exposure in units of multiple rows (for example, several dozen rows) rather than performing the global exposure on all the pixels at the same time. In addition, the global shutter method also encompasses a method of performing the global exposure on pixels in a predetermined region rather than on all the pixels in the part where the image appears.

The back-illuminated image sensor refers to an image sensor having a configuration in which a photoelectric conversion element is provided between a light-receiving surface on which the light from the subject is incident and a wiring layer provided with a wiring for a transistor, etc. that drive each of the pixels. The photoelectric conversion element receives light from a subject and converts the light into an electric signal. Examples of the photoelectric conversion element include a photodiode (PD).

The imaging device 1A includes, for example, a pixel array section 111, a vertical driver 112, a column signal processor 113, a data storage 119, a horizontal driver 114, a system controller 115, and a signal processor 118.

In the imaging device 1A, the pixel array section 111 is formed on a semiconductor substrate 11 (which will be described later). Peripheral circuits including, without limitation, the vertical driver 112, the column signal processor 113, the data storage 119, the horizontal driver 114, the system controller 115, and the signal processor 118 are formed on, for example, the same semiconductor substrate 11 on which the pixel array section 111 is also formed.

The pixel array section 111 includes multiple sensor pixels 121 (unit pixels) each including a photoelectric converter 51 (which will be described later). The photoelectric converter 51 generates electric charge corresponding to an amount of the light incident from the subject, and accumulates the generated electric charge. As illustrated in FIG. 1, the sensor pixels 121 are arranged in each of a horizontal direction (a row direction) and a vertical direction (a column direction). In the pixel array section 111, a pixel drive line 116 is wired along the row direction for each pixel row including the sensor pixels 121 arranged in a single line in the row direction; and a vertical signal line (VSL) 117 is wired along the column direction for each pixel column including the sensor pixels 121 arranged in a single line in the column direction.

The vertical driver 112 includes a shift register, an address decoder, etc. The vertical driver 112 drives all of the multiple sensor pixels 121 in the pixel array section 111 at the same time or drives them on a pixel row unit basis by supplying a signal or the like to each of the multiple sensor pixels 121 via corresponding one of the multiple pixel drive lines 116.

A signal outputted from each of the sensor pixels 121 in the pixel row selectively scanned by the vertical driver 112 is supplied to the column signal processor 113 via corresponding one of the VSLs 117. The column signal processor 113 performs predetermined signal processing on the signal outputted from each of the unit pixels in the selected row via the VSL 117 for each of the pixel columns of the pixel array section 111, and temporarily holds the image signal after the signal processing.

Specifically, the column signal processor 113 includes, for example, a shift register, an address decoder, etc., and performs a noise removal process, a correlated double sampling process, an A/D (Analog/Digital) conversion A/D conversion process of an analog image signal, etc. to generate a digital pixel signal. The column signal processor 113 supplies the generated pixel signal to the signal processor 118.

The horizontal driver 114 includes a shift register, an address decoder, etc., and sequentially selects a unit circuit corresponding to the pixel column of the column signal processor 113. Such selective scanning by the horizontal driver 114 allows the pixel signals subjected to the signal processing by the column signal processor 113 for respective unit circuits to be sequentially outputted to the signal processor 118.

The system controller 115 includes a timing generator, etc. The timing generator generates various timing signals. The system controller 115 performs a driving control of the vertical driver 112, the column signal processor 113, and the horizontal driver 114 on the basis of the timing signals generated by the timing generator.

The signal processor 118 performs signal processing such as arithmetic processing on the pixel signals supplied from the column signal processor 113 while temporarily storing data in the data storage 119 on an as-needed basis, and outputs an image signal including each of the pixel signals.

The data storage 119 temporarily holds, upon the signal processing performed by the signal processor 118, data necessary for the signal processing.

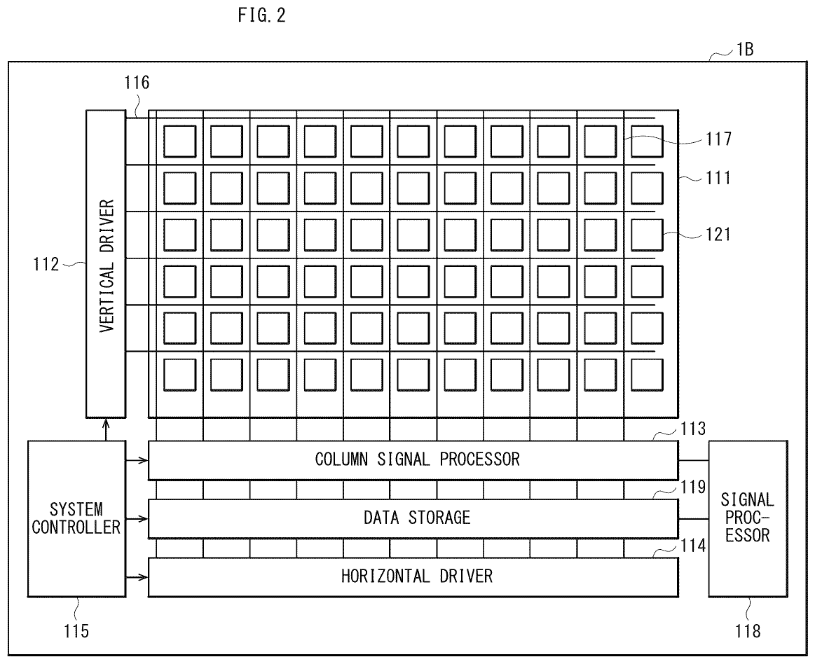

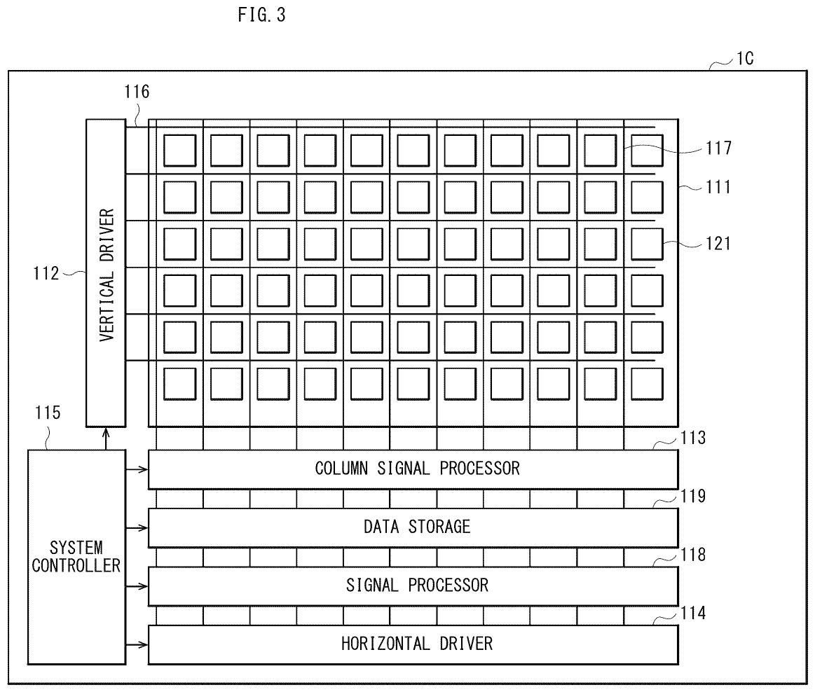

Note that the imaging device 1 of the present disclosure is not limited to the imaging device 1A illustrated in FIG. 1, and may have a configuration like that of an imaging device 1B illustrated in FIG. 2 or an imaging device 1C illustrated in FIG. 3, for example. FIG. 2 is a block diagram illustrating a configuration example of functions of the imaging device 1B as a first modification example according to the embodiment of the present disclosure. FIG. 3 is a block diagram illustrating a configuration example of functions of the imaging device 1C as a second modification example according to the embodiment of the present disclosure.

In the imaging device 1B in FIG. 2, the data storage 119 is disposed between the column signal processor 113 and the horizontal driver 114, and the pixel signal outputted from the column signal processor 113 is supplied to the signal processor 118 via the data storage 119.

In the imaging device 1C of FIG. 3, the data storage 119 and the signal processor 118 are disposed in parallel between the column signal processor 113 and the horizontal driver 114. In the imaging device 1C, the column signal processor 113 performs the A/D conversion that converts an analog pixel signal to a digital pixel signal on the basis of each column of the pixel array section 111 or on the basis of multiple columns of the pixel array section 111.

### Circuit Configuration of Sensor Pixel

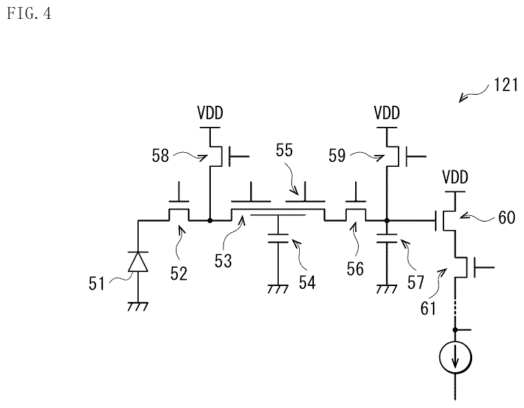

Next, with reference to FIG. 4, a description is given of a circuit configuration of the sensor pixel 121 formed in the pixel array section 111 in FIG. 1. FIG. 4 illustrates an example of the circuit configuration of the sensor pixel 121 illustrated in FIG. 1, etc.

In the example in FIG. 4, the sensor pixel 121 in the pixel array section 111 includes the photoelectric converter 51, a first transfer transistor (TRZ) 52, a second transfer transistor (TRY) 53, an electric charge holder (MEM) 54, a third transfer transistor (TRX) 55, a fourth transfer transistor (TRG) 56, an electric charge-voltage converter (FD) 57, a discharge transistor (OFG) 58, a reset transistor (RST) 59, an amplification transistor (AMP) 60, and a selection transistor (SEL) 61.

In addition, in this example, the TRZ 52, the TRY 53, the TRZ 55, the TRG 56, the OFG 58, the RST 59, the AMP 60, and the SEL 61 are each an N-type MOS transistor. Drive signals S52, S53, S55, S56, S58, S59, and S61 are respectively supplied to gate electrodes of the TRZ 52, the TRY 53, the TRZ 55, the TRG 56, the OFG 58, the RST 59, and the SEL 61. The drive signals S52, S53, S55, S56, S58, S59, and S61 are each a pulse signal in which a high level state is an active state (an ON state) and a low level state is a non-active state (an OFF state). Note that, hereinafter, bringing the drive signal into the active state is sometimes referred to as turning on the drive signal, and bringing the drive signal into the non-active state is sometimes referred to as turning off the drive signal.

The photoelectric converter 51 is, for example, a photoelectric conversion element including a PN junction photodiode. The photoelectric converter 51 receives light from a subject, generates electric charge corresponding to an amount of the received light by photoelectric conversion, and accumulates the generated electric charge.

The TRZ 52 is coupled between the photoelectric converter 51 and the TRY 53, and transfers the electric charge accumulated in the photoelectric converter 51 to the MEM 54 on the basis of the drive signal S52 applied to the gate electrode of the TRZ 52.

The TRY 53 controls a potential of the MEM 54 on the basis of the drive signal S53 applied to the gate electrode of the TRY 53. For example, when the drive signal S53 is turned on and the TRY 53 is turned on, the potential of the MEM 54 becomes deep. In addition, when the drive signal S53 is turned off and the TRY 53 is turned off, the potential of the MEM 54 becomes shallow. When the drive signal S52 and the drive signal S53 are turned on and the TRZ 52 and the TRY 53 are turned on, the electric charge accumulated in the photoelectric converter 51 is transferred to the MEM 54 via the TRZ 52 and the TRY 53.

The MEM 54 is a region that temporarily holds the electric charge accumulated in the photoelectric converter 51, in order to achieve a global shutter function.

The TRX 55 prevents, when the electric charge is transferred from the photoelectric converter 51 to the MEM 54, the electric charge from flowing back. For example, it is possible to prevent the electric charge from flowing back by turning off the TRY 53 and thereafter turning off the TRX 55.

The TRG 56 is coupled between the TRX 55 and the FD 57, and transfers the electric charge held in the MEM 54 to the FD 57 on the basis of the drive signal S56 applied to the gate electrode of the TRG 56. For example, when the drive signal S53 is turned off, the TRY 53 is turned off, the drive signal S55 and the drive signal S56 are turned on, and the TRX 55 and the TRG 56 are turned on, the electric charge held in the MEM 54 is transferred to the FD 57 via the TRX 55 and the TRG 56.

The FD 57 is a floating diffusion region that converts the electric charge transferred from the MEM 54 via the TRG 56 into an electric signal (e.g., a voltage signal) and outputs the electric signal. The RST 59 is coupled to the FD 57, and the vertical signal line VSL is coupled to the FD 57 via the AMP 60 and the SEL 61.

The OFG 58 has a drain coupled to a power source VDD and a source coupled to a wiring between the TRZ 52 and the TRY 53. The OFG 58 initializes the photoelectric converter 51, in other words, resets the photoelectric converter 51, on the basis of a drive signal OFG applied to the gate electrode of the OFG 58. For example, when the drive signal S52 and the drive signal S58 are turned on and the TRZ 52 and the OFG 58 are turned on, a potential of the photoelectric converter 51 is reset to a voltage level of the power source VDD. That is, the photoelectric converter 51 is initialized.

In addition, the OFG 58 forms an overflow path between the TRZ 52 and the power source VDD, and discharges the electric charge overflown from the photoelectric converter 51 to the power source VDD.

The RST 59 has a drain coupled to the power source VDD and a source coupled to the FD 57. The RST 59 initializes, in other words, resets, each of the regions from the MEM 54 to the FD 57 on the basis of the drive signal S59 applied to the gate electrode of the RST 59. For example, when the drive signal S55, the drive signal S56, and the drive signal S59 are turned on and the TRX 55, the TRG 56, and the RST 59 are turned on, a potential of each of the MEM 54 and the FD 57 is reset to the voltage level of the power source VDD. That is, each of the MEM 54 and the FD 57 is initialized.

The AMP 60 has the gate electrode coupled to the FD 57 and a drain coupled to the power source VDD, and serves as an input section of a source follower circuit that reads the electric charge obtained by the photoelectric conversion performed by the photoelectric converter 51. That is, a source of the AMP 60 being coupled to the vertical signal line VSL via the SEL 61 causes the AMP 60 to form the source follower circuit together with a constant current source coupled to one end of the vertical signal line VSL.

The SEL 61 is coupled between the source of the AMP 60 and the vertical signal line VSL, and the gate electrode of the SEL 61 receives the drive signal S61 as a selection signal. When the drive signal S61 is turned on, the SEL 61 is brought into a conductive state, and the sensor pixel 121 provided with the SEL 61 is brought into a selected state. When the sensor pixel 121 is in the selected state, the pixel signal outputted from the AMP 60 is read by the column signal processor 113 via the vertical signal line VSL.

In addition, in the pixel array section 111, multiple pixel drive lines 122 are wired for respective pixel rows, for example. Further, the drive signals S52, S53, S55, S56, S58, S59, and S61 are supplied to the selected sensor pixels 121 from the vertical driver 112 via the multiple pixel drive lines 122.

Note that the pixel circuit illustrated in FIG. 4 is an example of a pixel circuit usable in the pixel array section 111, and it is also possible to use a pixel circuit having any other configuration.

### Configuration of Sensor Pixel

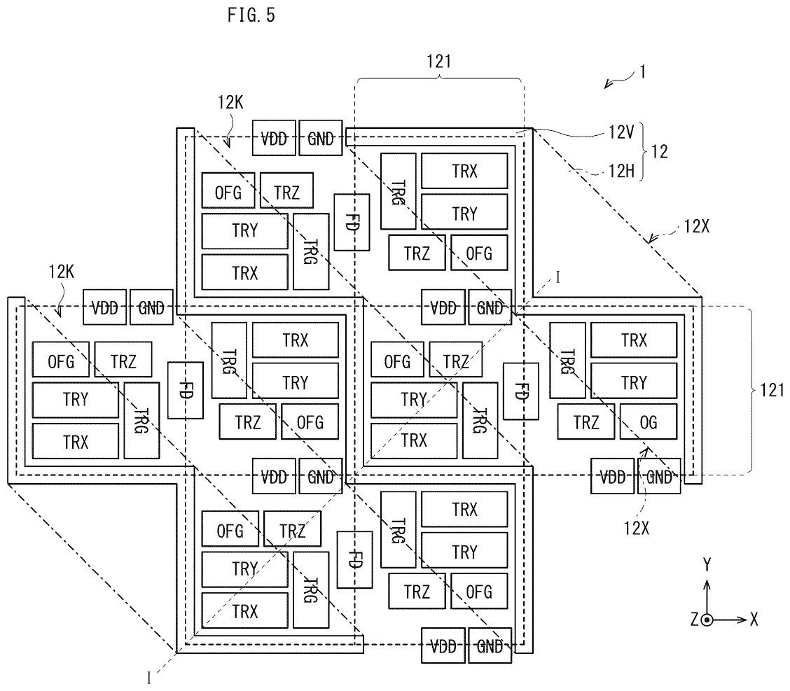

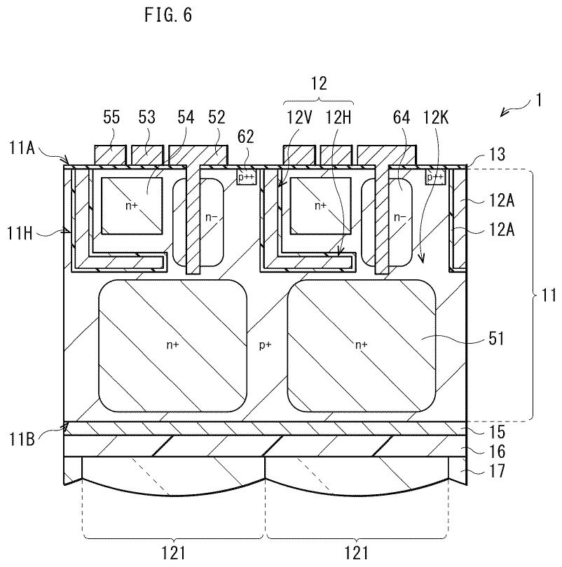

FIG. 5 schematically illustrates an example of a plan configuration of the pixel array section 111 in the imaging device 1. FIG. 6 schematically illustrates an example of a cross-sectional configuration of the imaging device 1, corresponding to a line I-I illustrated in FIG. 5. Herein, a plane in which the semiconductor substrate 11 extends is referred to as an XY plane, and a thickness direction of the semiconductor substrate 11 is referred to as a Z-axis direction. In addition, the row direction is regarded as an X-axis direction, and the column direction is regarded as a Y-axis direction.

Note that symbols “p” and “n” in the diagram represent a p-type semiconductor region and an n-type semiconductor region, respectively. Further, “+” or “−” after the symbol “p” represents an impurity concentration of the p-type semiconductor region. Similarly, “+” or “−” after the symbol “n” represents an impurity concentration of the n-type semiconductor region. Here, a greater number of “+” indicates a higher impurity concentration, and a greater number of “−” indicates a lower impurity concentration. This similarly applies to the drawings described hereinafter.

The imaging device 1 includes the semiconductor substrate 11, the photoelectric converter 51 embedded in the semiconductor substrate 11, the TRZ 52, the TRY 53, the MEM 54, the TRZ 55, the TRG 56, the FD 57, the OFG 58, a light-blocking section 12, a gate insulating layer 13, a fixed electric charge layer 15, a color filter layer 16, and a microlens 17. Note that, in the imaging device 1, a back surface 11B serves as a light receiving surface thereof.

The semiconductor substrate 11 includes a Si{111} substrate, for example. The Si{111} substrate is a substrate or a band region that includes a silicon single crystal having a (111) crystal orientation and having a crystal plane represented by {111} in the Miller index notation. It also encompasses a substrate or a descend having an orientation deviated by several degrees, e.g., an orientation deviated by several degrees from a {111} plane in the nearest <110> direction. It also encompasses a single crystal that has been grown. In addition, the {111} plane is any of a (111) plane, a (−111) plane, a (1-11) plane, a (11-1) plane, a (-1-11) plane, a (−11-1) plane, a (1-1-1) plane, and a (−1-1-1) plane that are crystal planes equivalent in symmetry. Here, a bar symbol used to represent an exponent in a negative direction of the Miller index is substituted with a minus symbol. In addition, the <110> direction may be any of a [110] direction, a [101] direction, a [011] direction, a [−110] direction, a [1-10] direction, a [−101] direction, a [10-1] direction, a [0-11] direction, a [01-1] direction, a [−1-10] direction, a [−10-1] direction, and a [0-1-1] direction that are crystal plane directions equivalent in symmetry, and may be interchangeably read as any of them. A direction parallel to the plane) and etching is performed. The semiconductor substrate 11 includes the back surface 11B that is the light receiving surface receiving light from a subject transmitted through the microlens 17 and the color filter layer 16, and a front surface 11A on opposite side to the back surface 11B.

The photoelectric converter 51 is what is called an embedded-type photodiode (PD) in which an n-type impurity region (p+) is formed inside a p-type impurity region (p+) formed in the semiconductor substrate 11. Each of the photoelectric converters 51 generates electric charge corresponding to an amount of received light, and accumulates the generated electric charge up to a certain amount.

The light-blocking section 12 is a member that functions to prevent incidence of light on the MEM 54, and is provided to surround the MEM 54. Specifically, the light-blocking section 12 includes, for example, a horizontal light-blocking part 12H and a vertical light-blocking part 12V. The horizontal light-blocking part 12H is provided on opposite side of the photoelectric converter 51 to the back surface 11B of the semiconductor substrate 11, and extends along a horizontal plane (the XY plane). The vertical light-blocking part 12V extends along an XZ plane and a YZ plane to be orthogonal to the horizontal light-blocking part 12H.

The vertical light-blocking part 12V is a wall part that is provided every other column in plan view. The vertical light-blocking part 12V is provided at a border part between the sensor pixels 121 adjacent to each other in the X-axis direction and the Y-axis direction, and extends in the X-axis direction and the Y-axis direction, in plan view. Specifically, the vertical light-blocking part 12V includes a row light-blocking part 12V1 and a column light-blocking part 12V2 formed along two respective sides, of the sensor pixel 121 having a rectangular shape, that are adjacent to each other, as illustrated in FIG. 5. In the pixel array section 111 as a whole, the vertical light-blocking part 12V is provided every other column, and is formed to be shifted, in each row, by an amount corresponding to one sensor pixel 121 in a direction parallel to the columns. In other words, the vertical light-blocking part 12V is formed at each of the two sides, of the sensor pixel having a substantially square shape, that are adjacent to each other, and is provided for each of the sensor pixels 121 positioned every other column and in a 45-degree oblique direction. That is, the vertical light-blocking part 12V is provided in a zigzag shape toward the <110> direction of the Si{111} substrate.

Note that the “45-degree oblique direction” described above allows a slight deviation, taking into consideration a manufacturing error. This is similarly applicable to the description below.

The horizontal light-blocking part 12H is positioned between the photoelectric converter 51 and the MEM 54 in the Z-axis direction, as illustrated in FIG. 6. The horizontal light-blocking part 12H is provided over the entire XY plane in the pixel array section 111 except for an opening 12K, as illustrated in FIG. 5. Specifically, in plan view, the horizontal light-blocking part 12H is provided on the XY plane surrounded by the row light-blocking part 12V1 and the column light-blocking part 12V2, and has an end 12X at a position connecting an end of the row light-blocking part 12V1 and an end of the column light-blocking part 12V2. In the pixel array section 111 as a whole, in plan view as illustrated in FIG. 5, the horizontal light-blocking part 12H is provided over the XY plane surrounded by the row light-blocking part 12V1 and the column light-blocking part 12V2 provided for each of the sensor pixels 121 positioned every other column and in the 45-degree oblique direction, and has the end 12X at or in the vicinity of a position connecting one and another of intersections of the row light-blocking parts 12V1 and the column light-blocking parts 12V2 provided for the respective sensor pixels 121 positioned every other column and in the 45-degree oblique direction. That is, the end 12X of the horizontal light-blocking part 12H is substantially parallel to the <110> direction of the Si{111} substrate.

This causes light incident from the back surface 11B and transmitted through the photoelectric converter 51 without being absorbed by the photoelectric converter 51 to be reflected at the horizontal light-blocking part 12H of the light-blocking section 12, and to be incident on the photoelectric converter 51 again. That is, the horizontal light-blocking part 12H of the light-blocking section 12 functions as a reflector, and functions to suppress generation of a noise due to incidence of the light transmitted through the photoelectric converter 51 on the MEM 54. In addition, the vertical light-blocking part 12V of the light-blocking section 12 functions to prevent generation of a noise such as color mixture due to incidence of leakage light from the adjacent sensor pixel 121 on the photoelectric converter 51.

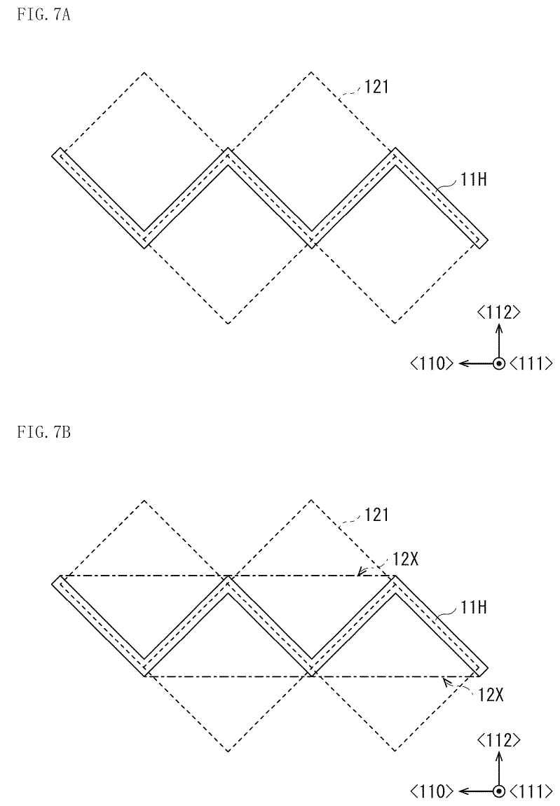

It is possible to form the horizontal light-blocking part 12H, with use of the Si{111} substrate as the semiconductor substrate 11, by forming a trench 11H having a zigzag shape in the <110> direction, and performing wet etching by an etching solution that allows for etching in the <110> direction of the semiconductor substrate 11, for example. Examples of such an etching solution include an alkaline aqueous solution. FIGS. 7A and 7B each schematically illustrate a process of forming the horizontal light-blocking part 12H. As illustrated in FIG. 7A, when the trench 11H having the zigzag shape is formed in the <110> direction and the alkaline etching is performed, the etching proceeds from a corner at which a crystal plane is disturbed. The etching proceeds until the corner does not appear anymore, and as illustrated in FIG. 7B, a space is formed that has an end (the end 12X) at a position connecting peaks of the trench 11H having the zigzag shape.

The light-blocking section 12 has a two-layer structure that includes an inner layer part 12A and an outer layer part 12B. The outer layer part 12B surrounds the inner layer part 12A. The inner layer part 12A includes, for example, a material including at least one of a single substance of a metal, a metal alloy, a metal nitride, or a metal silicide that has a light-blocking property. More specifically, examples of the material included in the inner layer part 12A include Al (aluminum), Cu (copper), Co (cobalt), W (tungsten), Ti (titanium), Ta (tantalum), Ni (nickel), Mo (molybdenum), Cr (chromium), Ir (iridium), platinum iridium, TiN (titanium nitride), a tungsten-silicon compound, and the like. Among them, Al (aluminum) is the most optically preferable material to be included. Note that the inner layer part 12A may include graphite, an organic material, or the like. The outer layer part 12B includes, for example, an insulating material such as SiOₓ (silicon oxide). The outer layer part 12B secures an electrically insulating property between the inner layer part 12A and the semiconductor substrate 11.

The gate electrode of each of the TRZ 52, the TRY 53, the TRX 55, the TRG 56, and the OFG 58 is provided on the front surface 11A of the semiconductor substrate 11 with the gate insulating layer 13 interposed therebetween. The MEM 54, which is an n-type semiconductor region (n+), is embedded in the semiconductor substrate 11, and is disposed between the front surface 11A and the horizontal light-blocking part 12H. The FD 57, a GND 62 (a well contact), and a VDD are provided on the front surface 11A of the semiconductor substrate 11. The FD 57 includes an n-type semiconductor region. The GND 62 is a p-type semiconductor region (p++) coupled to a ground (GND). The VDD is an n-type semiconductor region coupled to the power source VDD.

The TRZ 52 is what is called a vertical transistor. The TRZ 52 extends, as a gate electrode, downward along the Z-axis direction from the front surface 11A of the semiconductor substrate 11, and reaches the photoelectric converter 51 through the opening 12K and an n-type semiconductor region (n−) 64. The gate electrode of the TRZ 52 is provided in a Si remaining region 22 (a region corresponding to the opening 12K) other than a region occupied by the horizontal light-blocking part 12H in a horizontal plane. The TRZ 52 allows the electric charge moving from the photoelectric converter 51 toward the MEM 54 to pass therethrough.

Each of the FD 57, the GND 62, and the VDD is disposed at a border position between the two adjacent sensor pixels 121 adjacent to each other, and is shared by the two sensor pixels 121. Specifically, the FD 57 is disposed at a border position between the two sensor pixels 121 adjacent to each other in the X-axis direction, and is shared by the two sensor pixels 121 adjacent to each other in the X-axis direction. The two sensor pixels 121 adjacent to each other in the X-axis direction and sharing the FD 57 are referred to as an FD sharing unit. Each of the GND 62 and the VDD is disposed at a border position between the two sensor pixels 121 adjacent to each other in the Y-axis direction, and is shared by the two sensor pixels 121 adjacent to each other in the Y-axis direction. This reduces an area of an impurity-diffused region per pixel, and makes it possible to increase an area of the MEM 54.

The imaging device 1 further includes the fixed electric charge layer 15, the color filter layer 16, and the microlens 17 on the back surface 11B of the semiconductor substrate 11.

The fixed electric charge layer 15 has negative fixed electric charge in order to suppress generation of a dark current caused by an interface state of the back surface 11B serving as the light receiving surface of the semiconductor substrate 11. An electric field induced by the fixed electric charge layer 15 allows a hole accumulation layer to be formed in the vicinity of the back surface 11B of the semiconductor substrate 11. The hole accumulation layer suppresses generation of electrons from the back surface 11B.

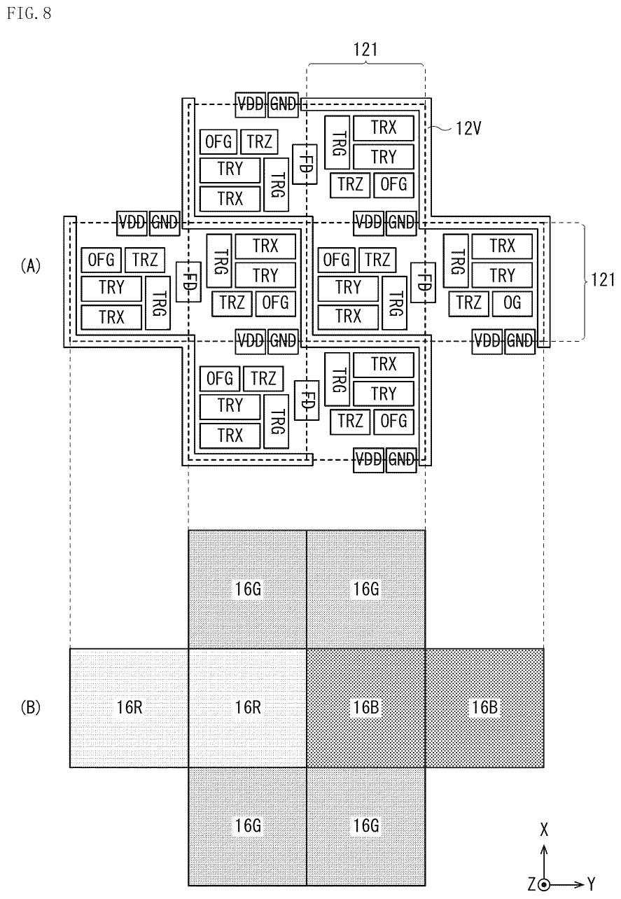

The color filter layer 16 is provided, for example, in contact with the fixed electric charge layer 15. The color filter layer 16 includes, for example, multiple color filters 16R, 16G, and 16B that selectively transmit red light (R), green light (G), and blue light (B), respectively. In the imaging device 1, for example, as illustrated in FIG. 8, color filters of the same color are provided for the two respective sensor pixels 121 (the FD sharing unit) sharing the FD 57. In addition, for example, as illustrated in FIG. 8, the color filters 16R, 16G, and 16B are so provided that the color filters 16R and the color filters 16B are provided for two respective FD sharing units disposed side by side in the X-axis direction, and the color filters 16G are provided for two respective FD sharing units that are disposed side by side in the Y-axis direction with the foregoing two FD sharing units interposed therebetween. This allows the center of gravity of the signal to be in a Bayer arrangement at the time of pixel addition, makes it easier to perform an arrangement transformation process. In addition, in the pixel array section 111 as a whole, same-color pixels are arranged obliquely. This allows both a vertical resolution decrease rate and a horizontal resolution decrease rate at the time of pixel addition to be ×1√2. This makes it possible to prevent the resolutions from being decreased greatly in only either of the two directions.

The microlens 17 is positioned on opposite side of the color filter layer 16 to the fixed electric charge layer 15, and is provided in contact with the color filter layer 16.

### Workings and Effects

As described above, the imaging device 1 of the present embodiment is provided with the light-blocking section 12 including the vertical light-blocking part 12V and the horizontal light-blocking part 12H that are provided at the two respective sides, of the sensor pixel 121 having the substantially square shape, that are adjacent to each other. The vertical light-blocking part 12V is provided for each of the sensor pixels 121 positioned every other column and in the 45-degree oblique direction. The horizontal light-blocking part 12H has the end 12X at or in the vicinity of the position connecting one and another of the intersections of the row light-blocking parts 12V1 and the column light-blocking parts 12V2 that are provided for the respective sensor pixels 121 positioned every other column and in the 45-degree oblique direction. It is therefore possible to improve light-blocking performance for the MEM 54 and electric charge transfer efficiency.

In addition, in the imaging device 1 of the present embodiment, the vertical light-blocking part 12V is provided in the zigzag shape toward the <110> direction of the Si{111} substrate. The end 12X of the horizontal light-blocking part 12H is substantially parallel to the <110> direction of the Si(111) substrate, and is formed to be inclined by 45° with respect to a development direction of the pixel array section 111. It is possible to easily form, without providing an etching stopper film or the like, the horizontal light-blocking part 12H by forming the trench 11H having the zigzag shape in the <110> direction that is to be the vertical light-blocking part 12V, and performing crystal anisotropic etching with use of the etching solution such as the alkaline aqueous solution. The vertical light-blocking part 12V thus has high dimension accuracy. It is thus possible to improve layout efficiency. Such an effect is more remarkable with smaller pixels.

Next, a description is given of second to fourth embodiments and Modification examples 1 to 3 of the present disclosure. Note that components corresponding to those of the imaging device 1 of the first embodiment described above are denoted with the same reference numerals, and descriptions thereof are omitted.

### 2. Modification Example 1

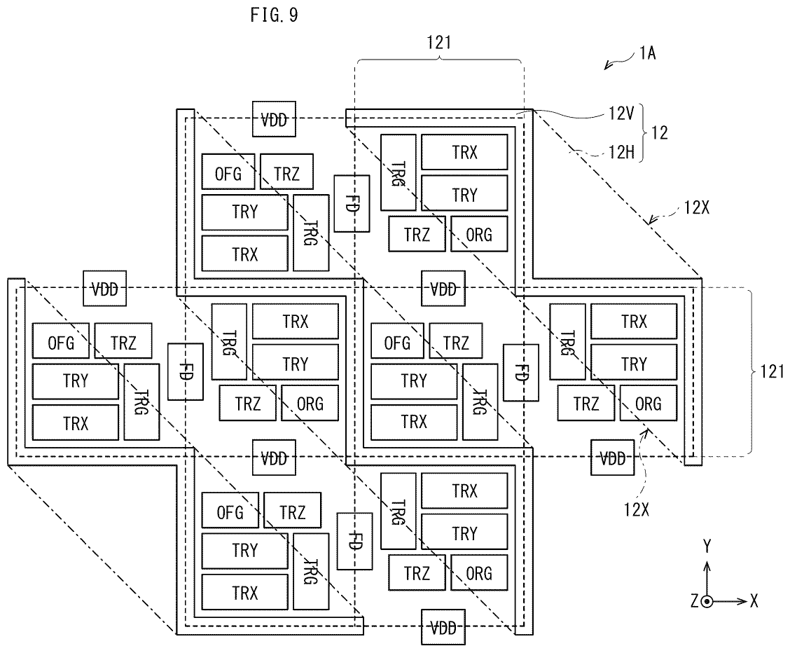

FIG. 9 schematically illustrates an example of a plan configuration of an imaging device (an imaging device 1A) according to Modification example 1 of the present disclosure.

The above-described first embodiment has dealt with the example in which the FD 57 is disposed at the border position between the two sensor pixels 121 adjacent to each other in the X-axis direction, and the GND 62 and the VDD are disposed at the border position between the two sensor pixels 121 adjacent to each other in the Y-axis direction. In contrast, in the imaging device 1A of the present modification example, the GND 62 is disposed for each of the sensor pixels 121, and the VDD is disposed at the border position between the two sensor pixels 121 adjacent to each other in the Y-axis direction. Except for these points, the imaging device 1A of the present modification example has a configuration substantially similar to that of the imaging device 1 of the first embodiment described above.

As described above, in the imaging device 1A of the present modification example, the layout of the sensor pixels 121 adjacent to each other in one of the X-axis direction and the Y-axis direction is point-symmetric with respect to a center of the two sensor pixels 121 adjacent to each other. This eliminates a difference in structure between the sensor pixels 121 and makes it possible to reduce a difference in a dark signal or the like between the pixels, in addition to achieving the effects of the first embodiment described above.

### 3. Second Embodiment

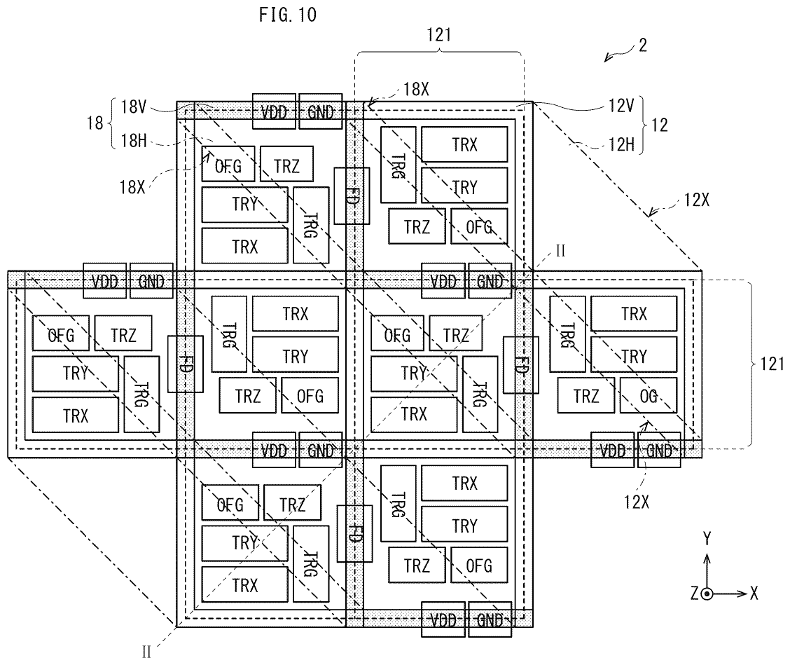

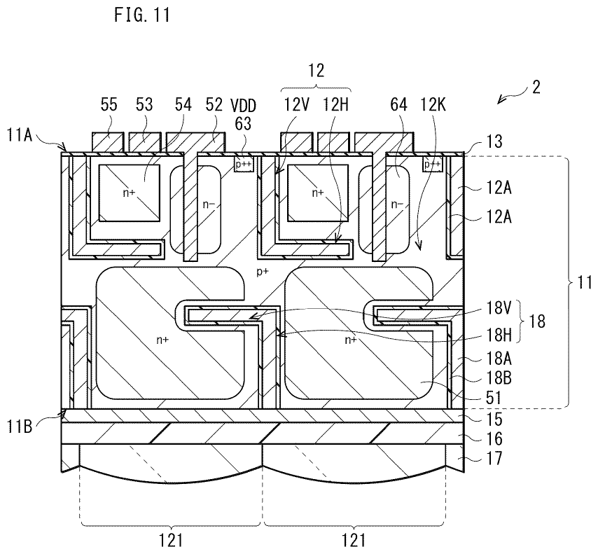

FIG. 10 schematically illustrates an example of a plan configuration of an imaging device (an imaging device 2) according to the second embodiment of the present disclosure. FIG. 11 schematically illustrates an example of a cross-sectional configuration corresponding to a line II-II illustrated in FIG. 10.

The first embodiment described above has dealt with the example in which the light-blocking section 12 including the horizontal light-blocking part 12H and the vertical light-blocking part 12V is provided as the member functioning to prevent incidence of light on the MEM 54. The horizontal light-blocking part 12H extends along the horizontal plane (the XY plane) between the photoelectric converter 51 and the MEM 54. The vertical light-blocking part 12V extends along the XZ plane and the YZ plane, and is orthogonal to the horizontal light-blocking part 12H from the front surface 11A side of the semiconductor substrate 11. In contrast, the imaging device 2 of the present embodiment is further provided with a light-blocking section 18 including a horizontal light-blocking part 18H and a vertical light-blocking part 18V. The horizontal light-blocking part 18H extends in a region corresponding to the opening 12K. The vertical light-blocking part 18V extends along the XZ plane and the YZ plane, and is orthogonal to the horizontal light-blocking part 18H from the back surface 11B side of the semiconductor substrate 11. Except for these points, the imaging device 2 has a configuration substantially similar to that of the imaging device 1 of the first embodiment described above.

The vertical light-blocking part 18V is a wall part that is provided every other column in plan view. The vertical light-blocking part 18V is provided at a border part between sensor pixels 181 adjacent to each other in the X-axis direction and the Y-direction, and extends in the X-axis direction and the Y-axis direction, in plan view. Specifically, the vertical light-blocking part 18V includes a row light-blocking part 18V1 and a column light-blocking part 18V2 formed along two respective sides, of the sensor pixel 181 having a rectangular shape as illustrated in FIG. 10, that are adjacent to each other, where no vertical light-blocking part 12V is provided. In the pixel array section 111 as a whole, as with the vertical light-blocking part 12V, the vertical light-blocking part 18V is provided every other column, and is formed to be shifted, in each row, by an amount corresponding to one sensor pixel 181 in a direction parallel to the columns. In other words, the vertical light-blocking part 18V is formed at each of the two sides, of the sensor pixel 181 having a substantially square shape, that are adjacent to each other, and is provided for each of the sensor pixels 181 positioned every other column and in the 45-degree oblique direction. That is, the vertical light-blocking part 18V is provided in a zigzag shape toward the <110> direction of the Si{111} substrate.

The horizontal light-blocking part 18H is provided closer to the front surface 11A of the semiconductor substrate 11 than the horizontal light-blocking part 12H as illustrated in FIG. 11. The horizontal light-blocking part 18H is so provided over the entire XY plane in the pixel array section 111 as to divide a portion of the photoelectric converter 51 in the Z-axis direction. Specifically, in plan view, the horizontal light-blocking part 18H is provided in the XY plane surrounded by the row light-blocking part 18V1 and the column light-blocking part 18V2, and has an end 18X at a position connecting an end of the row light-blocking part 18V1 and an end of the column light-blocking part 18V2. In the pixel array section 111 as a whole, in plan view as illustrated in FIG. 10, the horizontal light-blocking part 18H is provided over the XY plane surrounded by the row light-blocking part 18V1 and the column light-blocking part 18V2 that are provided for each of the sensor pixels 181 positioned every other column and in the 45-degree oblique direction, and has the end 18X at or in the vicinity of a position connecting one and another of intersections of the row light-blocking parts 18V1 and the column light-blocking parts 18V2 that are provided for the respective sensor pixels 181 positioned every other column and in the 45-degree oblique direction. That is, the end 18X of the horizontal light-blocking part 18H is substantially parallel to the <110> direction of the Si(111) substrate.

As with the horizontal light-blocking part 12H, it is possible to form the horizontal light-blocking part 18H, with use of the Si{111} substrate as the semiconductor substrate 11, by forming a trench 11H having a zigzag shape in the <110> direction, and performing wet etching by an etching solution that allows for etching in the <110> direction of the semiconductor substrate 11, for example. Examples of such an etching solution include an alkaline aqueous solution.

The light-blocking section 18 has a two-layer structure that includes an inner layer part 18A and an outer layer part 18B surrounding the inner layer part 18A. The inner layer part 18A includes, for example, a material including at least one of a single substance of a metal, a metal alloy, a metal nitride, or a metal silicide that has a light-blocking property. More specifically, examples of the material included in the inner layer part 18A include Al (aluminum), Cu (copper), Co (cobalt), W (tungsten), Ti (titanium), Ta (tantalum), Ni (nickel), Mo (molybdenum), Cr (chromium), Ir (iridium), platinum iridium, TiN (titanium nitride), a tungsten-silicon compound, and the like. Among them, Al (aluminum) is the most optically preferable material to be included. Note that the inner layer part 18A may include graphite, an organic material, or the like. The outer layer part 18B includes, for example, an insulating material such as SiOₓ (silicon oxide). The outer layer part 18B secures an electrically insulating property between the inner layer part 18A and the semiconductor substrate 11.

As described above, the imaging device 2 of the present embodiment is provided with the light-blocking section 18 in addition to the light-blocking section 12. The light-blocking section 18 includes the horizontal light-blocking part 18H and the vertical light-blocking part 18V. The horizontal light-blocking part 18H extends in the region corresponding to the opening 12K. The vertical light-blocking part 18V extends along the XZ plane and the YZ plane and is orthogonal to the horizontal light-blocking part 18H from the back surface 11B side of the semiconductor substrate 11. It is therefore possible to further prevent the incidence of the light transmitted through the photoelectric converter 51 on the MEM 54, and to further improve the light-blocking performance for the MEM 54.

### 4. Third Embodiment

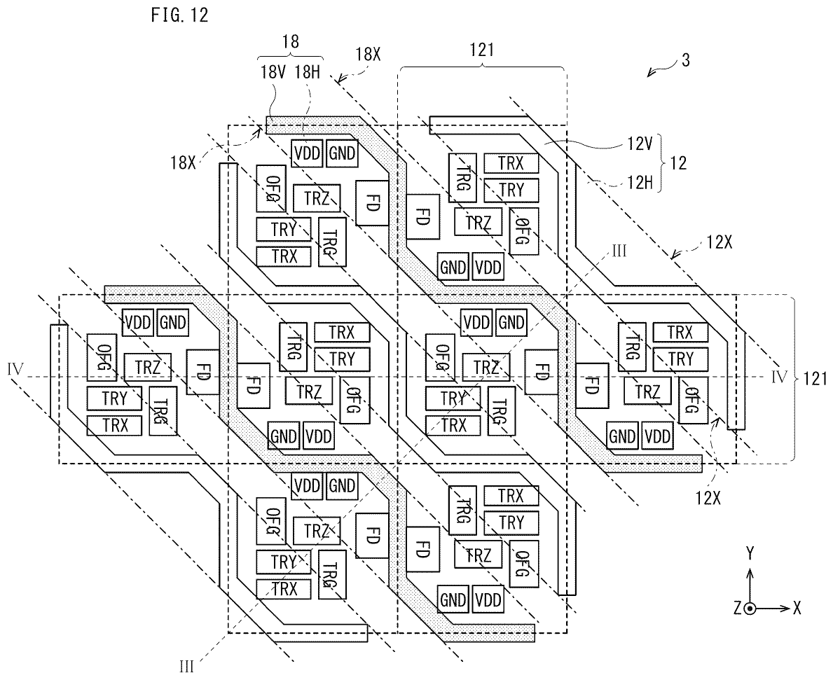

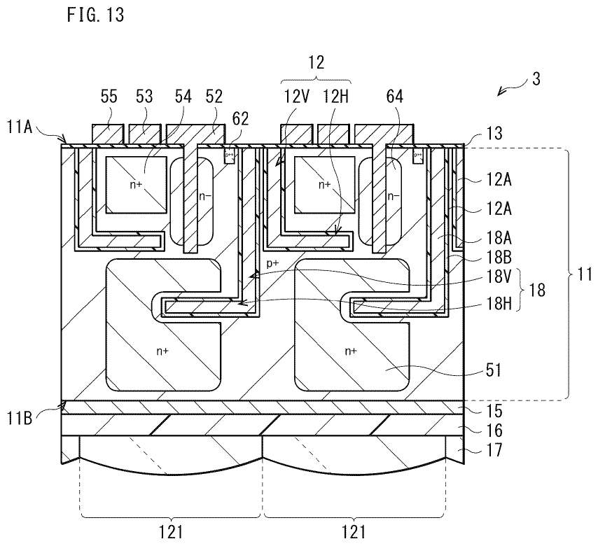

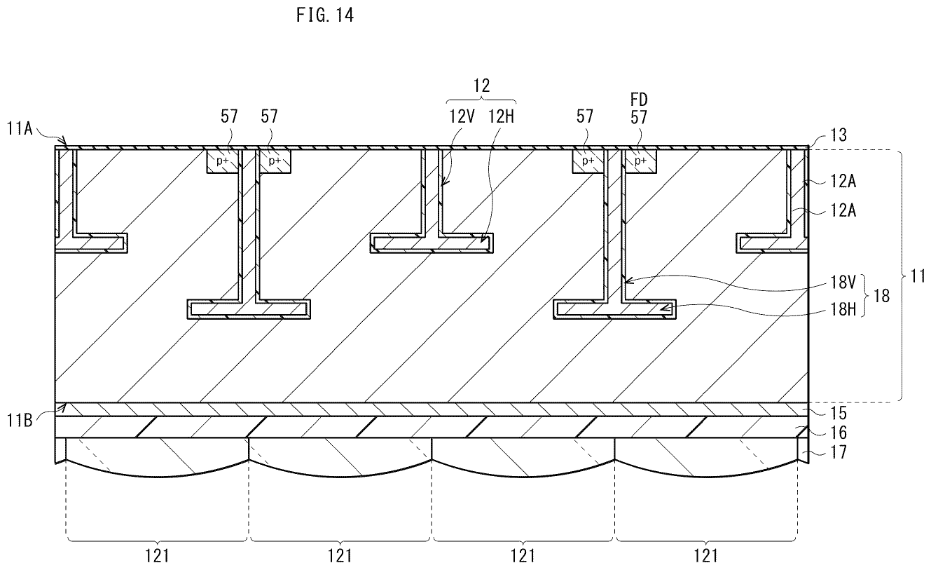

FIG. 12 schematically illustrates an example of a plan configuration of an imaging device (an imaging device 3) according to the third embodiment of the present disclosure. FIG. 13 schematically illustrates an example of a cross-sectional configuration corresponding to a line III-III illustrated in FIG. 12. FIG. 14 schematically illustrates an example of a cross-sectional configuration corresponding to a line IV-IV illustrated in FIG. 12.

The second embodiment described above has dealt with the example in which the light-blocking section 18 is provided from the back surface 11B side of the semiconductor substrate. In contrast, the imaging device 3 of the present embodiment has, as illustrated in FIG. 12, a layout in which the vertical light-blocking part 12V of the light-blocking section 12 and the vertical light-blocking part 18V of the light-blocking section 18 avoid four corners of the closest sensor pixel 121. In addition, the vertical light-blocking part 18V of the light-blocking section 18 is provided from the front surface 11A side of the semiconductor substrate 11, together with the vertical light-blocking part 12V of the light-blocking section 12. Except for these points, the imaging device 3 has a configuration substantially similar to that of the imaging device 1 of the second

### Embodiment Described Above.

As described above, in the imaging device 3 of the present embodiment, the vertical light-blocking part 18V of the light-blocking section 18 is provided from the front surface 11A side of the semiconductor substrate 11, together with the vertical light-blocking part 12V of the light-blocking section 12. It is thus possible to allow for formation by a front end process, unlike a case where the vertical light-blocking part 18V and the trench to be the horizontal light-blocking part 18H are formed from the back surface 11B as in the second embodiment described above. This allows for recovery, by heat, from a damage to the silicon single crystal of the semiconductor substrate 11, and makes it possible to improve a white point defect.

Note that in the imaging device 3, the FD 57 is provided for each of the sensor pixels 121, along the vertical light-blocking part 18V, of the light-blocking section 18, that extends at the border part between the two sensor pixels 121 adjacent to each other in the X-axis direction. The FDs 57 provided along the vertical light-blocking part 18V for the two respective sensor pixels 121 adjacent to each other in the X-axis direction are couplable by a shortest wiring. It is thus possible to sufficiently suppress a decrease in charge-voltage conversion efficiency.

### 5. Modification Example 2

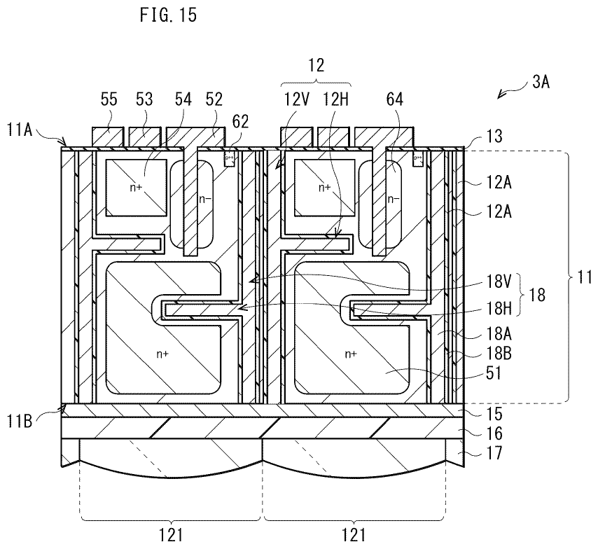

FIG. 15 schematically illustrates an example of a cross-sectional configuration of an imaging device (an imaging device 3A) according to Modification example 2 of the present disclosure.

For example, the vertical light-blocking part 12V of the light-blocking section 12 and the vertical light-blocking part 18V of the light-blocking section 18 of the third embodiment described above may be provided through between the front surface 11A and the back surface 11B of the semiconductor substrate 11. It is possible to form the vertical light-blocking parts 12V and 18V provided through between the front surface 11A and the back surface 11B of the semiconductor substrate 11 by forming a space extending in the XY plane to be the horizontal light-blocking parts 12H and 18H and thereafter, further continuing trench digging.

As described above, in the imaging device 3 of the present modification example, the vertical light-blocking part 12V of the light-blocking section 12 and the vertical light-blocking part 18V of the light-blocking section 18 are provided through between the front surface 11A and the back surface 11B of the semiconductor substrate 11. It is thus possible to suppress color mixture or the like due to incidence of leakage light from the adjacent sensor pixel 121 on the photoelectric converter 51.

### 6. Fourth Embodiment

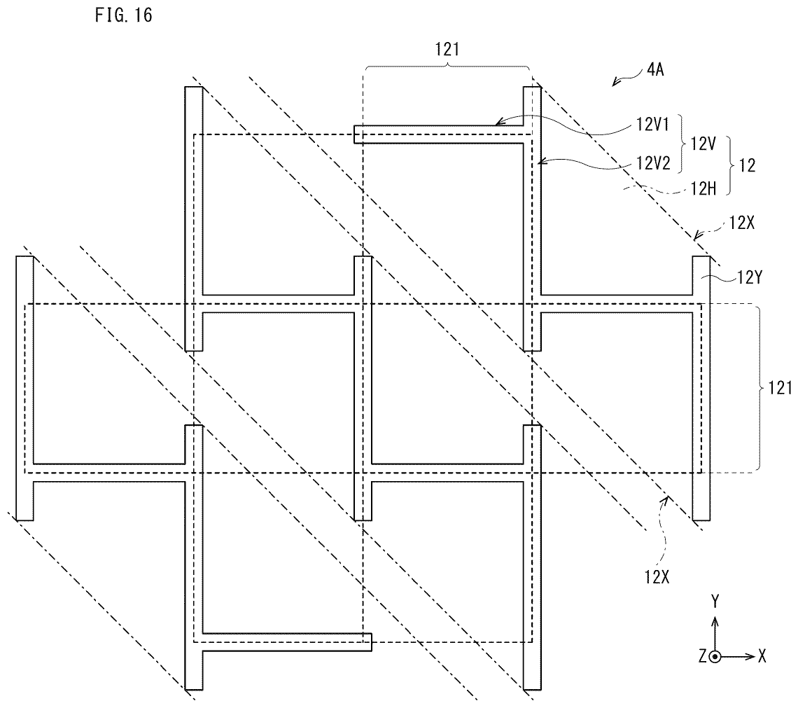

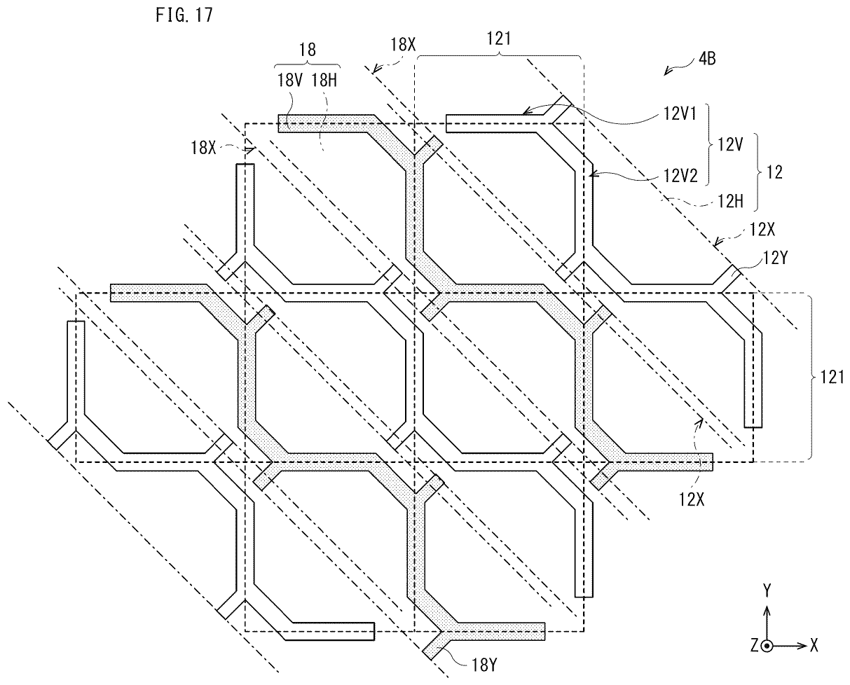

FIG. 16 schematically illustrates an example of a plan configuration of an imaging device (an imaging device 4A) according to a fourth embodiment of the present disclosure. FIG. 17 schematically illustrates an example of a plan configuration of an imaging device (an imaging device 4B) according to the fourth embodiment of the present disclosure.

The vertical light-blocking part 12V having the zigzag shape that is formed at the two sides, of the sensor pixel 121 having the substantially square shape, adjacent to each other and that is provided for each of the sensor pixels 121 positioned every other column and in the 45-degree oblique direction may protrude in the X-axis direction or the Y-axis direction at each of the intersections of the row light-blocking parts 12V1 and the column light-blocking parts 12V2, as illustrated in FIG. 16. Provision of such a protruding part 12Y allows the end 12X of the horizontal light-blocking part 12H to be formed at or in the vicinity of a position connecting one and another of leading ends of the protruding parts 12Y. That is, a formation region of the horizontal light-blocking part 12H is increased, and it is thus possible to improve the light-blocking performance for the MEM 54.

In addition, in a case where the light-blocking sections 12 and 18 are provided from the front surface 11A of the semiconductor substrate 11 as in the third embodiment described above, provided are the protruding parts 12Y and 18Y so protruding in the 45-degree oblique direction that the vertical light-blocking parts 12V and 18V are arranged in a staggered manner at a position where the vertical light-blocking parts 12V and 18V are closest to each other, as illustrated in FIG. 17. This allows the horizontal light-blocking part 12H and the horizontal light-blocking part 18H overlap each other by an amount corresponding to the protruding parts 12Y and 18Y in plan view, and thus makes it possible to further improve the light-blocking performance for the MEM 54.

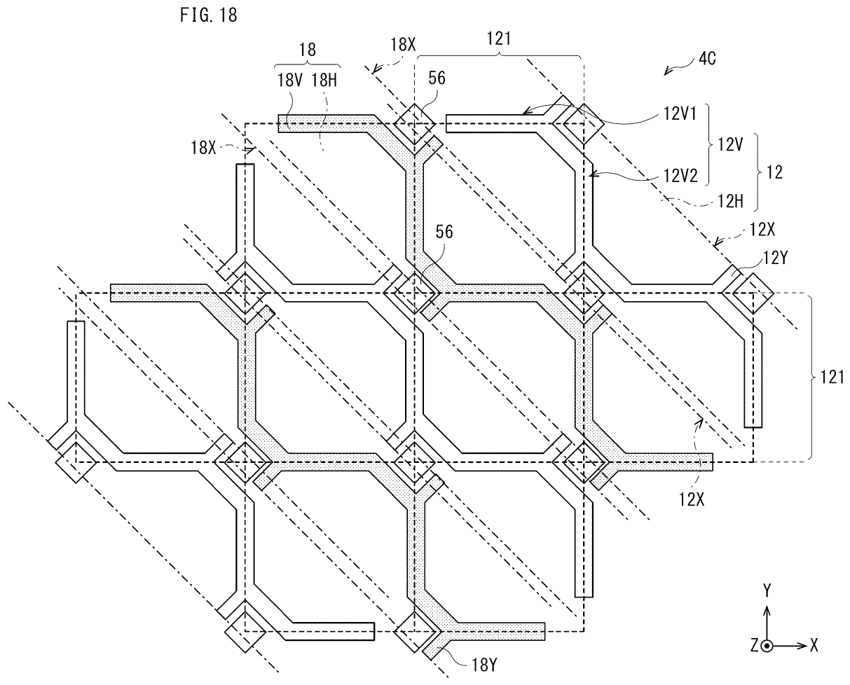

Further, for example, between the protruding parts 12Y and 18Y protruding in the 45-degree oblique direction in the staggered manner as illustrated in FIG. 17, the GND 62 to which a fixed potential is applied may be disposed, as in an imaging device 4C illustrated in FIG. 18. This improves area efficiency. In addition, this allows the vertical light-blocking parts 12V and 18V and the protruding parts 12Y and 18Y thereof to serve as element isolators, which leads to relaxation of an electric field.

As described above, in each of the imaging devices 4A, 4B, and 4C of the present embodiment, in a case where the protruding part 12Y protruding in the X-axis direction or the Y-axis direction at the intersection of the row light-blocking part 12V1 and the column light-blocking part 12V2 is provided, or in a case where the light-blocking sections 12 and 18 are provided from the front surface 11A of the semiconductor substrate 11, provided are the protruding parts 12Y and 18Y so protruding in the 45-degree oblique direction that the vertical light-blocking parts 12V and 18V are arranged in the staggered manner at the position where the vertical light-blocking parts 12V and 18V are closest to each other. This increases a formation region of the horizontal light-blocking parts 12H and 18H. It is thus possible to further improve the light-blocking performance for the MIEM 54, as compared with the first embodiment, etc. described above.

### 7. Modification Example 3

FIG. 19 schematically illustrates an example of a plan configuration of an imaging device according to Modification example 3 of the present disclosure.

The first embodiment, etc. described above have dealt with the example in which the row light-blocking part 12V1 and the column light-blocking part 12V2 are continuous with each other; however, this is non-limiting. As illustrated in FIG. 19, the row light-blocking part 12V1 and the column light-blocking part 12V2 may be separated from each other. This reduces a stress caused by a difference in material between the semiconductor substrate 11 and the light-blocking section 12, and makes it possible to suppress occurrence of a crystal defect, a crack, or the like, warpage of a wafer, etc.

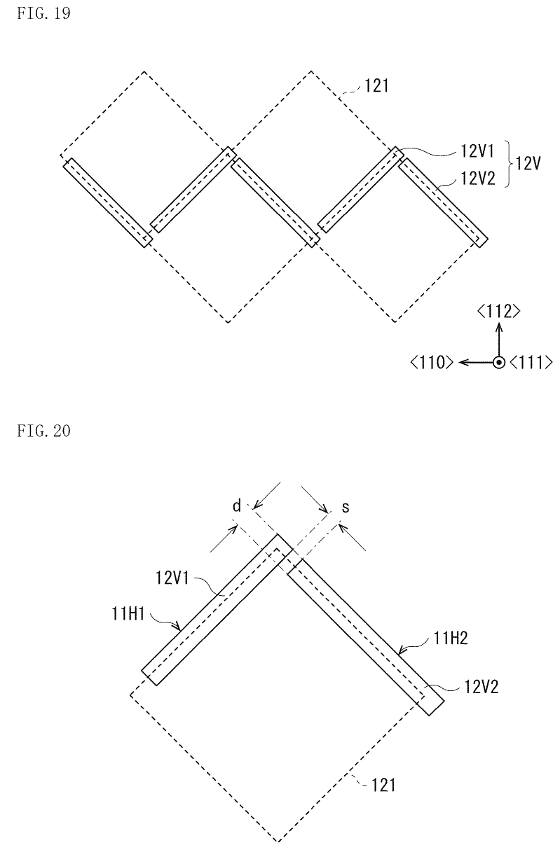

As illustrated in FIGS. 19 and 20, in a case where the row light-blocking part 12V1 and the column light-blocking part 12V2 are separated from each other, a space s between the row light-blocking part 12V1 and the column light-blocking part 12V2 and a protruding amount d of one of the light-blocking parts (e.g., the row light-blocking part 12V1) adjacent to another of the light-blocking parts (e.g., the column light-blocking part 12V2) have a relationship of s≤d. This allows a space between a trench 11H1 of the row light-blocking part 12V1 and a trench 11H2 of the column light-blocking part 12V2 that are separated from each other to be covered by the horizontal light-blocking part 12H. It is thus possible to achieve sufficient light-blocking performance.

### 8. Application Examples

### Application Example 1

For example, the imaging device 1 described above is applicable to, for example, any of various electronic apparatuses. Examples of such electronic apparatuses include: an imaging system such as a digital still camera or a digital video camera; a mobile phone having an imaging function; and any other apparatus having the imaging function.

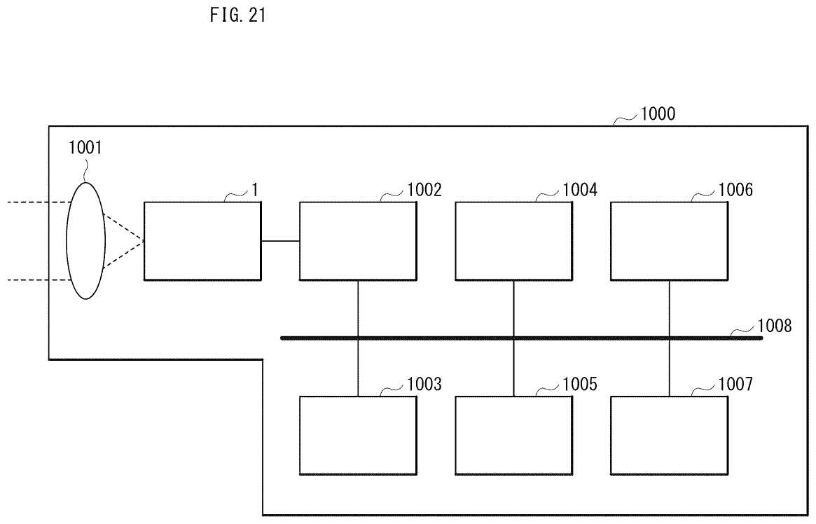

FIG. 21 is a block diagram illustrating an example of a configuration of an electronic apparatus 1000.

As illustrated in FIG. 21, the electronic apparatus 1000 includes an optical system 1001, the imaging device 1, and a DSP (Digital Signal Processor) 1002. The electronic apparatus 1000 has a configuration in which the DSP 1002, a memory 1003, a display device 1004, a recording device 1005, an operation system 1006, and a power supply system 1007 are coupled to each other via a bus 1008. The electronic apparatus 1000 is configured to capture a still image and a moving image.

The optical system 1001 includes one or multiple lenses. The optical system 1001 takes in incident light (image light) from a subject and forms an image on an imaging surface of the imaging device 1.

The imaging device 1, the imaging device 1A, or the like described above is applied to the imaging device 1. The imaging device 1 converts an amount of the incident light used to form the image on the imaging surface by the optical system 1001 into an electric signal on a pixel unit basis, and supplies the electric signal to the DSP 1002 as a pixel signal.

The DSP 1002 performs various kinds of signal processing on the signal from the imaging device 1, acquires an image, and causes data of the image to be temporarily stored in the memory 1003. The data of the image stored in the memory 1003 is, for example, recorded in the recording device 1005, or supplied to the display device 1004 to allow the image to be displayed. In addition, the operation system 1006 receives various operations performed by a user, and supplies an operation signal to each block of the electronic apparatus 1000. The power supply system 1007 supplies electric power necessary to drive each block of the electronic apparatus 1000.

### Application Example 2

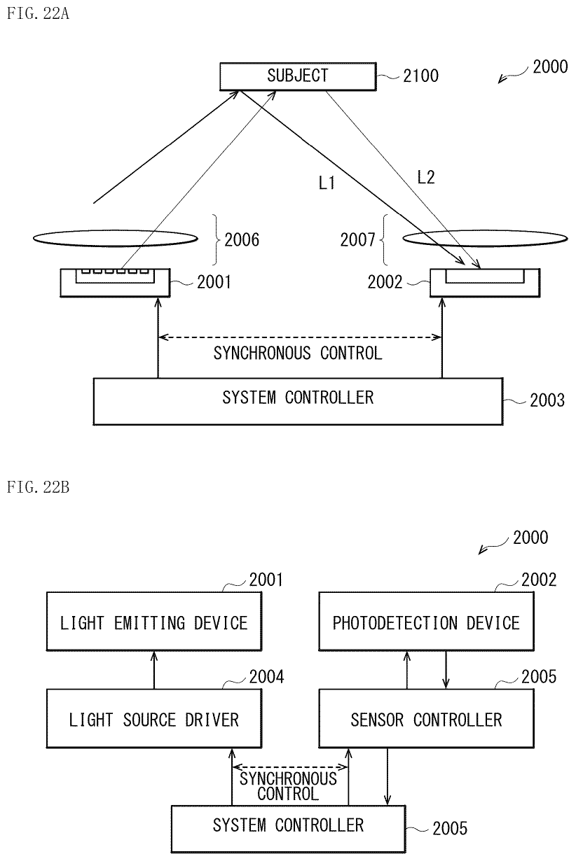

FIG. 22A schematically illustrates an example of an overall configuration of a photodetection system 2000 including the imaging device 1, for example. FIG. 22B illustrates an example of a circuit configuration of the photodetection system 2000. The photodetection system 2000 includes a light emitting device 2001 as a light source unit that emits infrared light L2, and a photodetection device 2002 as a light receiving unit. As the photodetection device 2002, it is possible to use the above-described imaging device 1, for example. The photodetection system 2000 may further include a system controller 2003, a light source driver 2004, a sensor controller 2005, a light-source-side optical system 2006, and a camera-side optical system 2007.

The photodetection device 2002 is configured to detect light L1 and the light L2. The light L1 is light in which ambient light from an outside is reflected by a subject (an object to be measured) 2100 (FIG. 22A). The light L2 is light emitted by the light emitting device 2001 and thereafter reflected by the subject 2100. The light L1 is, for example, visible light, and the light L2 is, for example, infrared light. The light L1 is detectable by a photoelectric converter of the photodetection device 2002, and the light L2 is detectable by a photoelectric conversion region in the photodetection device 2002. It is possible to obtain image information of the subject 2100 from the light L1, and to obtain distance information between the subject 2100 and the photodetection system 2000 from the light L2. The photodetection system 2000 is mountable on, for example, an electronic apparatus such as a smartphone or a mobile body such as a vehicle. The light emitting device 2001 may include, for example, a semiconductor laser, a surface-emitting semiconductor laser, or a vertical cavity surface emitting laser (VCSEL). As a method of detecting, by the photodetection device 2002, the light L2 emitted from the light emitting device 2001, for example, an iTOF method may be employed; however, this is non-limiting. In the iTOF method, the photoelectric converter is configured to measure a distance to the subject 2100 on the basis of, for example, a time of flight (Time-of-Flight; TOF). For example, a structured light method or a stereo vision method may also be employed as the method of detecting, by the photodetection device 2002, the light L2 emitted from the light emitting device 2001. For example, in the structured light method, it is possible to measure a distance between the photodetection system 2000 and the subject 2100 by projecting light having a predetermined pattern onto the subject 2100, and analyzing a degree of distortion of the projected pattern. Further, in the stereo vision method, it is possible to measure the distance between the photodetection system 2000 and the subject by, for example, using two or more cameras and acquiring two or more images in which the subject 2100 is captured from two or more viewpoints different from each other. It is to be noted that the light emitting device 2001 and the photodetection device 2002 may be synchronously controlled by the system controller 2003.

### 9. Practical Application Examples

### Example of Practical Application to Endoscopic Surgery System

The technique (the present technology) of the present disclosure is applicable to various products. For example, the technique of the present disclosure may be applied to an endoscopic surgery system.

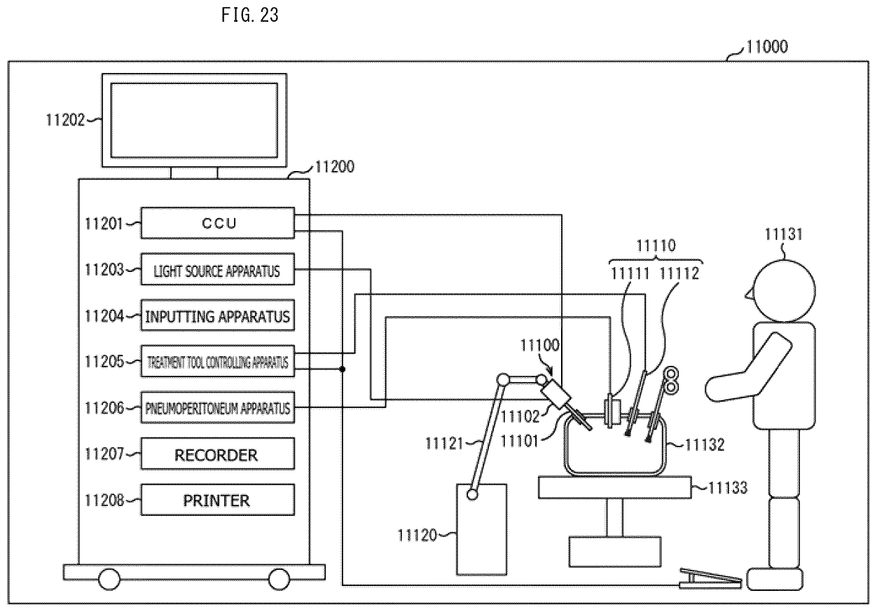

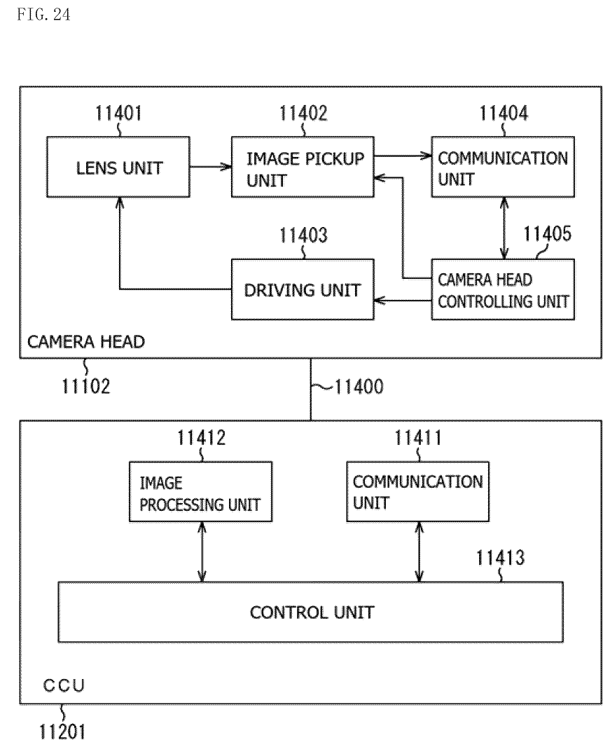

FIG. 23 is a view depicting an example of a schematic configuration of an endoscopic surgery system to which the technology according to an embodiment of the present disclosure (present technology) can be applied.

In FIG. 23, a state is illustrated in which a surgeon (medical doctor) 11131 is using an endoscopic surgery system 11000 to perform surgery for a patient 11132 on a patient bed 11133. As depicted, the endoscopic surgery system 11000 includes an endoscope 11100, other surgical tools 11110 such as a pneumoperitoneum tube 11111 and an energy device 11112, a supporting arm apparatus 11120 which supports the endoscope 11100 thereon, and a cart 11200 on which various apparatus for endoscopic surgery are mounted.

The endoscope 11100 includes a lens barrel 11101 having a region of a predetermined length from a distal end thereof to be inserted into a body cavity of the patient 11132, and a camera head 11102 connected to a proximal end of the lens barrel 11101. In the example depicted, the endoscope 11100 is depicted which includes as a rigid endoscope having the lens barrel 11101 of the hard type. However, the endoscope 11100 may otherwise be included as a flexible endoscope having the lens barrel 11101 of the flexible type.

The lens barrel 11101 has, at a distal end thereof, an opening in which an objective lens is fitted. A light source apparatus 11203 is connected to the endoscope 11100 such that light generated by the light source apparatus 11203 is introduced to a distal end of the lens barrel 11101 by a light guide extending in the inside of the lens barrel 11101 and is irradiated toward an observation target in a body cavity of the patient 11132 through the objective lens. It is to be noted that the endoscope 11100 may be a forward-viewing endoscope or may be an oblique-viewing endoscope or a side-viewing endoscope.

An optical system and an image pickup element are provided in the inside of the camera head 11102 such that reflected light (observation light) from the observation target is condensed on the image pickup element by the optical system. The observation light is photo-electrically converted by the image pickup element to generate an electric signal corresponding to the observation light, namely, an image signal corresponding to an observation image. The image signal is transmitted as RAW data to a CCU 11201.

The CCU 11201 includes a central processing unit (CPU), a graphics processing unit (GPU) or the like and integrally controls operation of the endoscope 11100 and a display apparatus 11202. Further, the CCU 11201 receives an image signal from the camera head 11102 and performs, for the image signal, various image processes for displaying an image based on the image signal such as, for example, a development process (demosaic process).

The display apparatus 11202 displays thereon an image based on an image signal, for which the image processes have been performed by the CCU 11201, under the control of the CCU 11201.

The light source apparatus 11203 includes a light source such as, for example, a light emitting diode (LED) and supplies irradiation light upon imaging of a surgical region to the endoscope 11100.

An inputting apparatus 11204 is an input interface for the endoscopic surgery system 11000. A user can perform inputting of various kinds of information or instruction inputting to the endoscopic surgery system 11000 through the inputting apparatus 11204. For example, the user would input an instruction or a like to change an image pickup condition (type of irradiation light, magnification, focal distance or the like) by the endoscope 11100.

A treatment tool controlling apparatus 11205 controls driving of the energy device 11112 for cautery or incision of a tissue, sealing of a blood vessel or the like. A pneumoperitoneum apparatus 11206 feeds gas into a body cavity of the patient 11132 through the pneumoperitoneum tube 11111 to inflate the body cavity in order to secure the field of view of the endoscope 11100 and secure the working space for the surgeon. A recorder 11207 is an apparatus capable of recording various kinds of information relating to surgery. A printer 11208 is an apparatus capable of printing various kinds of information relating to surgery in various forms such as a text, an image or a graph.

It is to be noted that the light source apparatus 11203 which supplies irradiation light when a surgical region is to be imaged to the endoscope 11100 may include a white light source which includes, for example, an LED, a laser light source or a combination of them. Where a white light source includes a combination of red, green, and blue (RGB) laser light sources, since the output intensity and the output timing can be controlled with a high degree of accuracy for each color (each wavelength), adjustment of the white balance of a picked up image can be performed by the light source apparatus 11203. Further, in this case, if laser beams from the respective RGB laser light sources are irradiated time-divisionally on an observation target and driving of the image pickup elements of the camera head 11102 are controlled in synchronism with the irradiation timings. Then images individually corresponding to the R, G and B colors can be also picked up time-divisionally. According to this method, a color image can be obtained even if color filters are not provided for the image pickup element.

Further, the light source apparatus 11203 may be controlled such that the intensity of light to be outputted is changed for each predetermined time. By controlling driving of the image pickup element of the camera head 11102 in synchronism with the timing of the change of the intensity of light to acquire images time-divisionally and synthesizing the images, an image of a high dynamic range free from underexposed blocked up shadows and overexposed highlights can be created.

Further, the light source apparatus 11203 may be configured to supply light of a predetermined wavelength band ready for special light observation. In special light observation, for example, by utilizing the wavelength dependency of absorption of light in a body tissue to irradiate light of a narrow band in comparison with irradiation light upon ordinary observation (namely, white light), narrow band observation (narrow band imaging) of imaging a predetermined tissue such as a blood vessel of a superficial portion of the mucous membrane or the like in a high contrast is performed. Alternatively, in special light observation, fluorescent observation for obtaining an image from fluorescent light generated by irradiation of excitation light may be performed. In fluorescent observation, it is possible to perform observation of fluorescent light from a body tissue by irradiating excitation light on the body tissue (autofluorescence observation) or to obtain a fluorescent light image by locally injecting a reagent such as indocyanine green (ICG) into a body tissue and irradiating excitation light corresponding to a fluorescent light wavelength of the reagent upon the body tissue. The light source apparatus 11203 can be configured to supply such narrow-band light and/or excitation light suitable for special light observation as described above.

FIG. 24 is a block diagram depicting an example of a functional configuration of the camera head 11102 and the CCU 11201 depicted in FIG. 23.

The camera head 11102 includes a lens unit 11401, an image pickup unit 11402, a driving unit 11403, a communication unit 11404 and a camera head controlling unit 11405. The CCU 11201 includes a communication unit 11411, an image processing unit 11412 and a control unit 11413. The camera head 11102 and the CCU 11201 are connected for communication to each other by a transmission cable 11400.

The lens unit 11401 is an optical system, provided at a connecting location to the lens barrel 11101. Observation light taken in from a distal end of the lens barrel 11101 is guided to the camera head 11102 and introduced into the lens unit 11401. The lens unit 11401 includes a combination of a plurality of lenses including a zoom lens and a focusing lens.

The number of image pickup elements which is included by the image pickup unit 11402 may be one (single-plate type) or a plural number (multi-plate type). Where the image pickup unit 11402 is configured as that of the multi-plate type, for example, image signals corresponding to respective R, G and B are generated by the image pickup elements, and the image signals may be synthesized to obtain a color image. The image pickup unit 11402 may also be configured so as to have a pair of image pickup elements for acquiring respective image signals for the right eye and the left eye ready for three dimensional (3D) display. If 3D display is performed, then the depth of a living body tissue in a surgical region can be comprehended more accurately by the surgeon 11131. It is to be noted that, where the image pickup unit 11402 is configured as that of stereoscopic type, a plurality of systems of lens units 11401 are provided corresponding to the individual image pickup elements.

Further, the image pickup unit 11402 may not necessarily be provided on the camera head 11102. For example, the image pickup unit 11402 may be provided immediately behind the objective lens in the inside of the lens barrel 11101.

The driving unit 11403 includes an actuator and moves the zoom lens and the focusing lens of the lens unit 11401 by a predetermined distance along an optical axis under the control of the camera head controlling unit 11405. Consequently, the magnification and the focal point of a picked up image by the image pickup unit 11402 can be adjusted suitably.

The communication unit 11404 includes a communication apparatus for transmitting and receiving various kinds of information to and from the CCU 11201. The communication unit 11404 transmits an image signal acquired from the image pickup unit 11402 as RAW data to the CCU 11201 through the transmission cable 11400.

In addition, the communication unit 11404 receives a control signal for controlling driving of the camera head 11102 from the CCU 11201 and supplies the control signal to the camera head controlling unit 11405. The control signal includes information relating to image pickup conditions such as, for example, information that a frame rate of a picked up image is designated, information that an exposure value upon image picking up is designated and/or information that a magnification and a focal point of a picked up image are designated.

It is to be noted that the image pickup conditions such as the frame rate, exposure value, magnification or focal point may be designated by the user or may be set automatically by the control unit 11413 of the CCU 11201 on the basis of an acquired image signal. In the latter case, an auto exposure (AE) function, an auto focus (AF) function and an auto white balance (AWB) function are incorporated in the endoscope 11100.

The camera head controlling unit 11405 controls driving of the camera head 11102 on the basis of a control signal from the CCU 11201 received through the communication unit 11404.

The communication unit 11411 includes a communication apparatus for transmitting and receiving various kinds of information to and from the camera head 11102. The communication unit 11411 receives an image signal transmitted thereto from the camera head 11102 through the transmission cable 11400.

Further, the communication unit 11411 transmits a control signal for controlling driving of the camera head 11102 to the camera head 11102. The image signal and the control signal can be transmitted by electrical communication, optical communication or the like.

The image processing unit 11412 performs various image processes for an image signal in the form of RAW data transmitted thereto from the camera head 11102.

The control unit 11413 performs various kinds of control relating to image picking up of a surgical region or the like by the endoscope 11100 and display of a picked up image obtained by image picking up of the surgical region or the like. For example, the control unit 11413 creates a control signal for controlling driving of the camera head 11102.

Further, the control unit 11413 controls, on the basis of an image signal for which image processes have been performed by the image processing unit 11412, the display apparatus 11202 to display a picked up image in which the surgical region or the like is imaged. Thereupon, the control unit 11413 may recognize various objects in the picked up image using various image recognition technologies. For example, the control unit 11413 can recognize a surgical tool such as forceps, a particular living body region, bleeding, mist when the energy device 11112 is used and so forth by detecting the shape, color and so forth of edges of objects included in a picked up image. The control unit 11413 may cause, when it controls the display apparatus 11202 to display a picked up image, various kinds of surgery supporting information to be displayed in an overlapping manner with an image of the surgical region using a result of the recognition. Where surgery supporting information is displayed in an overlapping manner and presented to the surgeon 11131, the burden on the surgeon 11131 can be reduced and the surgeon 11131 can proceed with the surgery with certainty.

The transmission cable 11400 which connects the camera head 11102 and the CCU 11201 to each other is an electric signal cable ready for communication of an electric signal, an optical fiber ready for optical communication or a composite cable ready for both of electrical and optical communications.

Here, while, in the example depicted, communication is performed by wired communication using the transmission cable 11400, the communication between the camera head 11102 and the CCU 11201 may be performed by wireless communication.

One example of the endoscopic surgery system to which the technique according to the present disclosure is applicable has been described above. The technique according to the present disclosure is applicable to the image pickup unit 11402 in the configuration described above. Applying the technique according to the present disclosure to the image pickup unit 11402 improves detection accuracy.

Note that although the endoscopic surgery system has been described here as one example, the technique according to the present disclosure may be applied to, for example, any other system such as a microscopic surgery system.

### Example of Practical Application to Mobile Body

The technique according to the present disclosure is applicable to various products. For example, the technique according to the present disclosure may be implemented as a device mounted on any type of mobile bodies including, without limitation, an automobile, an electric vehicle, a hybrid electric vehicle, a motorcycle, a bicycle, a personal mobility, an airplane, a drone, a vessel, a robot, a construction machine, an agricultural machine (a tractor), and the like.

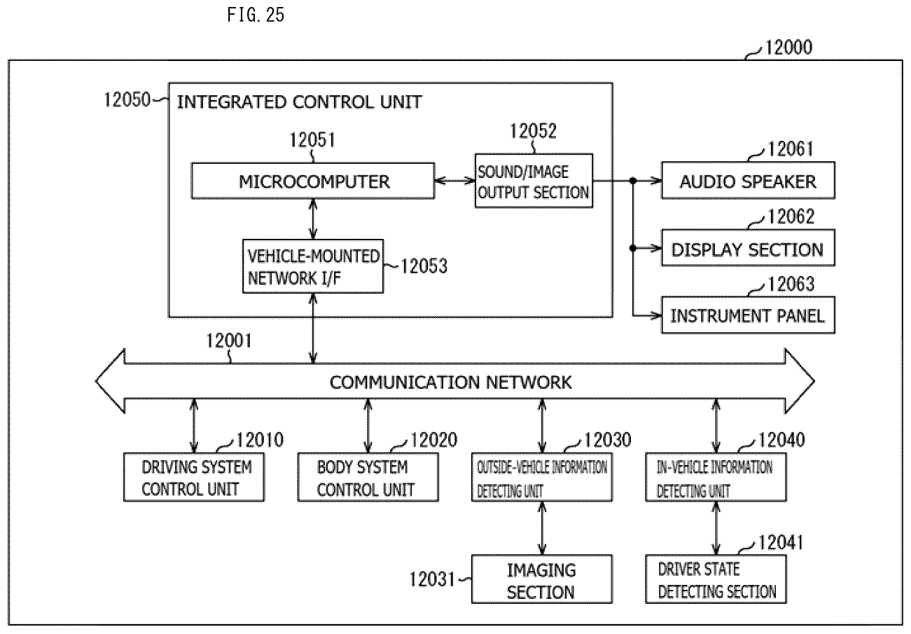

FIG. 25 is a block diagram depicting an example of schematic configuration of a vehicle control system as an example of a mobile body control system to which the technology according to an embodiment of the present disclosure can be applied.

The vehicle control system 12000 includes a plurality of electronic control units connected to each other via a communication network 12001. In the example depicted in FIG. 25, the vehicle control system 12000 includes a driving system control unit 12010, a body system control unit 12020, an outside-vehicle information detecting unit 12030, an in-vehicle information detecting unit 12040, and an integrated control unit 12050. In addition, a microcomputer 12051, a sound/image output section 12052, and a vehicle-mounted network interface (I/F) 12053 are illustrated as a functional configuration of the integrated control unit 12050.

The driving system control unit 12010 controls the operation of devices related to the driving system of the vehicle in accordance with various kinds of programs. For example, the driving system control unit 12010 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like.

The body system control unit 12020 controls the operation of various kinds of devices provided to a vehicle body in accordance with various kinds of programs. For example, the body system control unit 12020 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 12020. The body system control unit 12020 receives these input radio waves or signals, and controls a door lock device, the power window device, the lamps, or the like of the vehicle.

The outside-vehicle information detecting unit 12030 detects information about the outside of the vehicle including the vehicle control system 12000. For example, the outside-vehicle information detecting unit 12030 is connected with an imaging section 12031. The outside-vehicle information detecting unit 12030 makes the imaging section 12031 image an image of the outside of the vehicle, and receives the imaged image. On the basis of the received image, the outside-vehicle information detecting unit 12030 may perform processing of detecting an object such as a human, a vehicle, an obstacle, a sign, a character on a road surface, or the like, or processing of detecting a distance thereto.

The imaging section 12031 is an optical sensor that receives light, and which outputs an electric signal corresponding to a received light amount of the light. The imaging section 12031 can output the electric signal as an image, or can output the electric signal as information about a measured distance. In addition, the light received by the imaging section 12031 may be visible light, or may be invisible light such as infrared rays or the like.

The in-vehicle information detecting unit 12040 detects information about the inside of the vehicle. The in-vehicle information detecting unit 12040 is, for example, connected with a driver state detecting section 12041 that detects the state of a driver. The driver state detecting section 12041, for example, includes a camera that images the driver. On the basis of detection information input from the driver state detecting section 12041, the in-vehicle information detecting unit 12040 may calculate a degree of fatigue of the driver or a degree of concentration of the driver, or may determine whether the driver is dozing.

The microcomputer 12051 can calculate a control target value for the driving force generating device, the steering mechanism, or the braking device on the basis of the information about the inside or outside of the vehicle which information is obtained by the outside-vehicle information detecting unit 12030 or the in-vehicle information detecting unit 12040, and output a control command to the driving system control unit 12010. For example, the microcomputer 12051 can perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like.

In addition, the microcomputer 12051 can perform cooperative control intended for automated driving, which makes the vehicle to travel automatedly without depending on the operation of the driver, or the like, by controlling the driving force generating device, the steering mechanism, the braking device, or the like on the basis of the information about the outside or inside of the vehicle which information is obtained by the outside-vehicle information detecting unit 12030 or the in-vehicle information detecting unit 12040.

In addition, the microcomputer 12051 can output a control command to the body system control unit 12020 on the basis of the information about the outside of the vehicle which information is obtained by the outside-vehicle information detecting unit 12030. For example, the microcomputer 12051 can perform cooperative control intended to prevent a glare by controlling the headlamp so as to change from a high beam to a low beam, for example, in accordance with the position of a preceding vehicle or an oncoming vehicle detected by the outside-vehicle information detecting unit 12030.

The sound/image output section 12052 transmits an output signal of at least one of a sound and an image to an output device capable of visually or auditorily notifying information to an occupant of the vehicle or the outside of the vehicle. In the example of FIG. 25, an audio speaker 12061, a display section 12062, and an instrument panel 12063 are illustrated as the output device. The display section 12062 may, for example, include at least one of an on-board display and a head-up display.

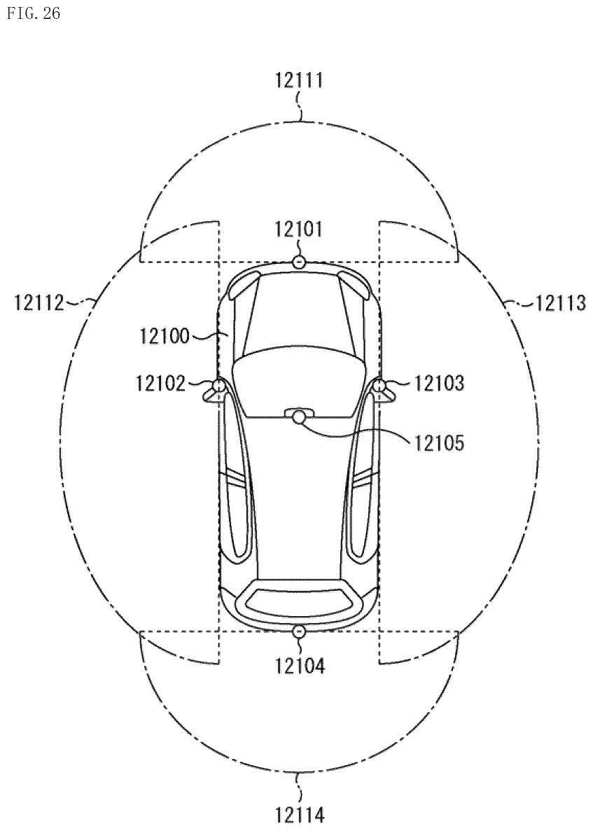

FIG. 26 is a diagram depicting an example of the installation position of the imaging section 12031.

In FIG. 26, the imaging section 12031 includes imaging sections 12101, 12102, 12103, 12104, and 12105.

The imaging sections 12101, 12102, 12103, 12104, and 12105 are, for example, disposed at positions on a front nose, sideview mirrors, a rear bumper, and a back door of the vehicle 12100 as well as a position on an upper portion of a windshield within the interior of the vehicle. The imaging section 12101 provided to the front nose and the imaging section 12105 provided to the upper portion of the windshield within the interior of the vehicle obtain mainly an image of the front of the vehicle 12100. The imaging sections 12102 and 12103 provided to the sideview mirrors obtain mainly an image of the sides of the vehicle 12100. The imaging section 12104 provided to the rear bumper or the back door obtains mainly an image of the rear of the vehicle 12100. The imaging section 12105 provided to the upper portion of the windshield within the interior of the vehicle is used mainly to detect a preceding vehicle, a pedestrian, an obstacle, a signal, a traffic sign, a lane, or the like.

Incidentally, FIG. 26 depicts an example of photographing ranges of the imaging sections 12101 to 12104. An imaging range 12111 represents the imaging range of the imaging section 12101 provided to the front nose. Imaging ranges 12112 and 12113 respectively represent the imaging ranges of the imaging sections 12102 and 12103 provided to the sideview mirrors. An imaging range 12114 represents the imaging range of the imaging section 12104 provided to the rear bumper or the back door. A bird's-eye image of the vehicle 12100 as viewed from above is obtained by superimposing image data imaged by the imaging sections 12101 to 12104, for

### Example.

At least one of the imaging sections 12101 to 12104 may have a function of obtaining distance information. For example, at least one of the imaging sections 12101 to 12104 may be a stereo camera constituted of a plurality of imaging elements, or may be an imaging element having pixels for phase difference detection.

For example, the microcomputer 12051 can determine a distance to each three-dimensional object within the imaging ranges 12111 to 12114 and a temporal change in the distance (relative speed with respect to the vehicle 12100) on the basis of the distance information obtained from the imaging sections 12101 to 12104, and thereby extract, as a preceding vehicle, a nearest three-dimensional object in particular that is present on a traveling path of the vehicle 12100 and which travels in substantially the same direction as the vehicle 12100 at a predetermined speed (for example, equal to or more than 0 km/hour). Further, the microcomputer 12051 can set a following distance to be maintained in front of a preceding vehicle in advance, and perform automatic brake control (including following stop control), automatic acceleration control (including following start control), or the like. It is thus possible to perform cooperative control intended for automated driving that makes the vehicle travel automatedly without depending on the operation of the driver or the like.

For example, the microcomputer 12051 can classify three-dimensional object data on three-dimensional objects into three-dimensional object data of a two-wheeled vehicle, a standard-sized vehicle, a large-sized vehicle, a pedestrian, a utility pole, and other three-dimensional objects on the basis of the distance information obtained from the imaging sections 12101 to 12104, extract the classified three-dimensional object data, and use the extracted three-dimensional object data for automatic avoidance of an obstacle. For example, the microcomputer 12051 identifies obstacles around the vehicle 12100 as obstacles that the driver of the vehicle 12100 can recognize visually and obstacles that are difficult for the driver of the vehicle 12100 to recognize visually. Then, the microcomputer 12051 determines a collision risk indicating a risk of collision with each obstacle. In a situation in which the collision risk is equal to or higher than a set value and there is thus a possibility of collision, the microcomputer 12051 outputs a warning to the driver via the audio speaker 12061 or the display section 12062, and performs forced deceleration or avoidance steering via the driving system control unit 12010. The microcomputer 12051 can thereby assist in driving to avoid collision.

At least one of the imaging sections 12101 to 12104 may be an infrared camera that detects infrared rays. The microcomputer 12051 can, for example, recognize a pedestrian by determining whether or not there is a pedestrian in imaged images of the imaging sections 12101 to 12104. Such recognition of a pedestrian is, for example, performed by a procedure of extracting characteristic points in the imaged images of the imaging sections 12101 to 12104 as infrared cameras and a procedure of determining whether or not it is the pedestrian by performing pattern matching processing on a series of characteristic points representing the contour of the object. When the microcomputer 12051 determines that there is a pedestrian in the imaged images of the imaging sections 12101 to 12104, and thus recognizes the pedestrian, the sound/image output section 12052 controls the display section 12062 so that a square contour line for emphasis is displayed so as to be superimposed on the recognized pedestrian. The sound/image output section 12052 may also control the display section 12062 so that an icon or the like representing the pedestrian is displayed at a desired position.

One example of the mobile body control system to which the technique according to the present disclosure is applicable has been described above. The technique according to the present disclosure is applicable to the imaging section 12031 in the configuration described above. Specifically, the imaging device (e.g., the imaging device 1A) according to any of the embodiments and the modification examples thereof described above is applicable to the imaging section 12031. Applying the technique according to the present disclosure to the imaging section 12031 makes it possible to obtain a captured image with less noise and higher resolution. It is therefore possible to allow the mobile body control system to perform a highly accurate control with use of the captured image.

Although the present technology has been described with reference to the first to fourth embodiments and Modification examples 1 to 3, the present technology is not limited to the embodiments, etc. described above, and various modifications may be made. For example, it is not necessary to include all of the components described in the embodiments, etc. described above, and conversely, any other component may be included. For example, in the imaging device 1 according to the first embodiment described above, an isolator or the like that electrically isolates the adjacent photoelectric converters 51 may be provided.

Note that the effects described herein are mere examples and non-limiting. In addition, any other effect may be achieved.

Note that the present technology may have any of the following configurations. According to the present technology having any of the following configurations, it is possible to obtain a light-blocking section having high dimension accuracy. It is thus possible to achieve an imaging device that achieves both superior light-blocking performance for an electric charge holder and superior electric charge transfer efficiency.
(1)

An imaging device including:
a semiconductor substrate including a first surface and a second surface that are opposed to each other, the semiconductor substrate including a pixel array section in which multiple unit pixels are arranged in an array in a row direction and a column direction;
a photoelectric converter that is provided on side of the second surface of the semiconductor substrate for each of the unit pixels, and generates electric charge corresponding to a light reception amount by photoelectric conversion;
an electric charge holder that is provided on side of the first surface of the semiconductor substrate for each of the unit pixels, and holds the electric charge transferred from the photoelectric converter; and
a first light-blocking section that is provided in the semiconductor substrate and is positioned between the photoelectric converter and the electric charge holder, the first light-blocking section including a first horizontal light-blocking part and a first vertical light-blocking part, the first horizontal light-blocking part extending in an in-plane direction of the semiconductor substrate, the first vertical light-blocking part being orthogonal to the first horizontal light-blocking part, in which
the first vertical light-blocking part includes a first row light-blocking part and a first column light-blocking part formed along two respective sides, of the unit pixel having a rectangular shape, that are adjacent to each other, the first vertical light-blocking part being provided for each of the unit pixels positioned every other column and in a 45-degree oblique direction, and
the first horizontal light-blocking part has, in plan view, an end at or in the vicinity of a position connecting one and another of intersections of the first row light-blocking parts and the first column light-blocking parts that are provided for the respective unit pixels positioned every other column and in the 45-degree oblique direction.
(2)

The imaging device according to (1) described above, in which
the semiconductor substrate includes a Si{111} substrate,
the multiple first vertical light-blocking parts provided for the respective unit pixels positioned every other column and in the 45-degree oblique direction are each provided in a zigzag shape toward a <110> direction of the Si{111} substrate, and
the end of each of the multiple first horizontal light-blocking parts provided for the respective unit pixels positioned every other column and in the 45-degree oblique direction is substantially parallel to the <110> direction of the Si{111} substrate.
(3)

The imaging device according to (1) or (2) described above, in which the multiple first vertical light-blocking parts provided for the respective unit pixels positioned every other column and in the 45-degree oblique direction are continuous with each other.
(4)

The imaging device according to any one of (1) to (3) described above, further including:
an electric charge-voltage converter that is provided on the first surface of the semiconductor substrate and to which the electric charge is transferred from the electric charge holder; and
a drain section that is provided on the first surface of the semiconductor substrate, to which the electric charge overflown from the photoelectric converter is discharged, and that is coupled to an electric power source, in which
the electric charge-voltage converter is shared by two of the unit pixels adjacent to each other in the row direction, and
the drain section is shared by two of the unit pixels adjacent to each other in the column direction.
(5)

The imaging device according to (4) described above, further including
a color filter layer that is disposed on the side of the second surface of the semiconductor substrate, and includes multiple color filters that selectively transmit light in respective wavelength ranges different from each other, in which
the color filters selectively transmitting the light in the respective wavelength ranges that are the same as each other are disposed in the two of the unit pixels adjacent to each other and sharing the electric charge-voltage converter.
(6)

The imaging device according to (4) described above, further including
multiple transistors that are provided on the side of the second surface of the semiconductor substrate for each of the unit pixels and form a pixel circuit, the pixel circuit outputting a pixel signal based on the electric charge outputted from the unit pixel P, in which
the multiple transistors provided in one of the two of the unit pixels adjacent to each other and sharing the electric charge-voltage converter and the multiple transistors provided in another of the two of the unit pixels adjacent to each other and sharing the electric charge-voltage converter are laid out point-symmetrically.
(7)

The imaging device according to any one of (1) to (6) described above, in which the multiple first vertical light-blocking parts provided for the respective unit pixels positioned every other column and in the 45-degree oblique direction include respective protruding parts provided at the intersections of the first row light-blocking parts and the first column light-blocking parts, the protruding parts each protruding in the row direction or the column direction.
(8)

The imaging device according to (7) described above, in which the end of each of the multiple first horizontal light-blocking parts provided for the respective unit pixels positioned every other column and in the 45-degree oblique direction is formed at a position connecting one and another of the respective protruding parts provided at the intersections of the first row light-blocking parts and the first column light-blocking parts.
(9)

The imaging device according to any one of (1) to (8) described above, in which the first vertical light-blocking part extends from the first surface toward the second surface of the semiconductor substrate.
(10)

The imaging device according to (9) described above, in which the first vertical light-blocking part is provided through between the first surface and the second surface of the semiconductor substrate.
(11)

The imaging device according to (9) described above, in which the first row light-blocking part and the first column light-blocking part are independent of each other.
(12)

The imaging device according to (11) described above, in which a spacing s between the first row light-blocking part and the first column light-blocking part and a protruding amount d of one of the light-blocking parts adjacent to another of the light-blocking parts have a relationship of s≤d.
(13)

The imaging device according to any one of (1) to (12) described above, further including
a second light-blocking section that is provided in the semiconductor substrate, the second light-blocking section including, in plan view, a second horizontal light-blocking part and a second vertical light-blocking part, the second horizontal light-blocking part extending in a direction in a plane of the semiconductor substrate in which the first horizontal light-blocking part is not formed, the second vertical light-blocking part being orthogonal to the second horizontal light-blocking part, in which
the second vertical light-blocking part includes a second row light-blocking part and a second column light-blocking part formed along two respective sides that are adjacent to each other and along which neither the first row light-blocking part nor the first column light-blocking part is formed, the second vertical light-blocking part being provided for each of the unit pixels positioned every other column and in the 45-degree oblique direction, and
the second horizontal light-blocking part has, in plan view, an end at or in the vicinity of a position connecting one and another of intersections of the second row light-blocking parts and the second column light-blocking parts that are provided for the respective unit pixels positioned every other column and in the 45-degree oblique direction.
(14)

The imaging device according to (13) described above, in which the second vertical light-blocking part extends from the second surface toward the first surface of the semiconductor substrate.
(15)

The imaging device according to (13) described above, in which the second vertical light-blocking part extends from the first surface toward the second surface of the semiconductor substrate.
(16)

The imaging device according to (14) described above, in which the second vertical light-blocking part is provided through between the second surface and the second surface of the semiconductor substrate.
(17)

The imaging device according to any one of (13) to (16) described above, in which the second horizontal light-blocking part is provided closer to the second surface than the first horizontal light-blocking part.
(18)

The imaging device according to any one of (13) to (17) described above, in which the first horizontal light-blocking part and the second horizontal light-blocking part partially overlap in plan view.
(19)

The imaging device according to any one of (13) to (18) described above, in which
the first vertical light-blocking part and the second vertical light-blocking part respectively include a first protruding part and a second protruding part at the respective intersections opposed to each other, the first protruding part and the second protruding part protruding in the 45-degree oblique direction in a staggered manner, and
a well contact is provided between the first protruding part and the second protruding part, the well contact applying a fixed potential to the semiconductor substrate.
(20)

An electronic apparatus including an imaging device,
the imaging device including
a semiconductor substrate including a first surface and a second surface that are opposed to each other, the semiconductor substrate including a pixel array section in which multiple unit pixels are arranged in an array in a row direction and a column direction,
a photoelectric converter that is provided on side of the second surface of the semiconductor substrate for each of the unit pixels, and generates electric charge corresponding to a light reception amount by photoelectric conversion,
an electric charge holder that is provided on side of the first surface of the semiconductor substrate for each of the unit pixels, and holds the electric charge transferred from the photoelectric converter, and
a first light-blocking section that is provided in the semiconductor substrate and is positioned between the photoelectric converter and the electric charge holder, the first light-blocking section including a first horizontal light-blocking part and a first vertical light-blocking part, the first horizontal light-blocking part extending in an in-plane direction of the semiconductor substrate, the first vertical light-blocking part being orthogonal to the first horizontal light-blocking part, in which
the first vertical light-blocking part includes a first row light-blocking part and a first column light-blocking part formed along two respective sides, of the unit pixel having a rectangular shape, that are adjacent to each other, the first vertical light-blocking part being provided for each of the unit pixels positioned every other column and in a 45-degree oblique direction, and
the first horizontal light-blocking part has, in plan view, an end at or in the vicinity of a position connecting one and another of intersections of the first row light-blocking parts and the first column light-blocking parts that are provided for the respective unit pixels positioned every other column and in the 45-degree oblique direction.

The present application claims the benefit of Japanese Priority Patent Application JP2022-147342 filed with the Japan Patent Office on Sep. 15, 2022, the entire contents of which are incorporated herein by reference.

It should be understood by those skilled in the art that various modifications, combinations, sub-combinations and alterations may occur depending on design requirements and other factors insofar as they are within the scope of the appended claims or the equivalents thereof.

What is claimed is:

1. An imaging device, comprising:
a semiconductor substrate including a first surface and a second surface that are opposed to each other, the semiconductor substrate including a pixel array section in which multiple unit pixels are arranged in an array in a row direction and a column direction;
a photoelectric converter that is provided on side of the second surface of the semiconductor substrate for each of the unit pixels, and generates electric charge corresponding to a light reception amount by photoelectric conversion;
an electric charge holder that is provided on side of the first surface of the semiconductor substrate for each of the unit pixels, and holds the electric charge transferred from the photoelectric converter; and
a first light-blocking section that is provided in the semiconductor substrate and is positioned between the photoelectric converter and the electric charge holder, the first light-blocking section including a first horizontal light-blocking part and a first vertical light-blocking part, the first horizontal light-blocking part extending in an in-plane direction of the semiconductor substrate, the first vertical light-blocking part being orthogonal to the first horizontal light-blocking part, wherein
the first vertical light-blocking part includes a first row light-blocking part and a first column light-blocking part formed along two respective sides, of the unit pixel having a rectangular shape, that are adjacent to each other, the first vertical light-blocking part being provided for each of the unit pixels positioned every other column and in a 45-degree oblique direction, and
the first horizontal light-blocking part has, in plan view, an end at or in vicinity of a position connecting one and another of intersections of the first row light-blocking parts and the first column light-blocking parts that are provided for the respective unit pixels positioned the every other column and in the 45-degree oblique direction.

2. The imaging device according to claim 1, wherein
the semiconductor substrate comprises a Si{111} substrate,
multiple the first vertical light-blocking parts provided for the respective unit pixels positioned the every other column and in the 45-degree oblique direction are each provided in a zigzag shape toward a <110> direction of the Si{111} substrate, and
the end of each of multiple the first horizontal light-blocking parts provided for the respective unit pixels positioned the every other column and in the 45-degree oblique direction is substantially parallel to the <110> direction of the Si{111} substrate.

3. The imaging device according to claim 1, wherein multiple the first vertical light-blocking parts provided for the respective unit pixels positioned the every other column and in the 45-degree oblique direction are continuous with each other.

4. The imaging device according to claim 1, further comprising:
an electric charge-voltage converter that is provided on the first surface of the semiconductor substrate and to which the electric charge is transferred from the electric charge holder; and
a drain section that is provided on the first surface of the semiconductor substrate, to which the electric charge overflown from the photoelectric converter is discharged, and that is coupled to an electric power source, wherein
the electric charge-voltage converter is shared by two of the unit pixels adjacent to each other in the row direction, and
the drain section is shared by two of the unit pixels adjacent to each other in the column direction.

5. The imaging device according to claim 4, further comprising
a color filter layer that is disposed on the side of the second surface of the semiconductor substrate, and includes multiple color filters that selectively transmit light in respective wavelength ranges different from each other, wherein
the color filters selectively transmitting the light in the respective wavelength ranges that are same as each other are disposed in the two of the unit pixels adjacent to each other and sharing the electric charge-voltage converter.

6. The imaging device according to claim 4, further comprising
multiple transistors that are provided on the side of the second surface of the semiconductor substrate for each of the unit pixels and form a pixel circuit, the pixel circuit outputting a pixel signal based on the electric charge outputted from the unit pixel P, wherein
the multiple transistors provided in one of the two of the unit pixels adjacent to each other and sharing the electric charge-voltage converter and the multiple transistors provided in another of the two of the unit pixels adjacent to each other and sharing the electric charge-voltage converter are laid out point-symmetrically.

7. The imaging device according to claim 1, wherein multiple the first vertical light-blocking parts provided for the respective unit pixels positioned the every other column and in the 45-degree oblique direction include respective protruding parts provided at the intersections of the first row light-blocking parts and the first column light-blocking parts, the protruding parts each protruding in the row direction or the column direction.

8. The imaging device according to claim 7, wherein the end of each of multiple the first horizontal light-blocking parts provided for the respective unit pixels positioned the every other column and in the 45-degree oblique direction is formed at a position connecting one and another of the respective protruding parts provided at the intersections of the first row light-blocking parts and the first column light-blocking parts.

9. The imaging device according to claim 1, wherein the first vertical light-blocking part extends from the first surface toward the second surface of the semiconductor substrate.

10. The imaging device according to claim 9, wherein the first vertical light-blocking part is provided through between the first surface and the second surface of the semiconductor substrate.

11. The imaging device according to claim 9, wherein the first row light-blocking part and the first column light-blocking part are independent of each other.

12. The imaging device according to claim 11, wherein a spacing s between the first row light-blocking part and the first column light-blocking part and a protruding amount d of one of the light-blocking parts adjacent to another of the light-blocking parts have a relationship of s≤d.

13. The imaging device according to claim 1, further comprising
a second light-blocking section that is provided in the semiconductor substrate, the second light-blocking section including, in plan view, a second horizontal light-blocking part and a second vertical light-blocking part, the second horizontal light-blocking part extending in a direction in a plane of the semiconductor substrate in which the first horizontal light-blocking part is not formed, the second vertical light-blocking part being orthogonal to the second horizontal light-blocking part, wherein
the second vertical light-blocking part includes a second row light-blocking part and a second column light-blocking part formed along two respective sides that are adjacent to each other and along which neither the first row light-blocking part nor the first column light-blocking part is formed, the second vertical light-blocking part being provided for each of the unit pixels positioned the every other column and in the 45-degree oblique direction, and
the second horizontal light-blocking part has, in plan view, an end at or in vicinity of a position connecting one and another of intersections of the second row light-blocking parts and the second column light-blocking parts that are provided for the respective unit pixels positioned the every other column and in the 45-degree oblique direction.

14. The imaging device according to claim 13, wherein the second vertical light-blocking part extends from the second surface toward the first surface of the semiconductor substrate.

15. The imaging device according to claim 13, wherein the second vertical light-blocking part extends from the first surface toward the second surface of the semiconductor substrate.

16. The imaging device according to claim 14, wherein the second vertical light-blocking part is provided through between the second surface and the second surface of the semiconductor substrate.

17. The imaging device according to claim 13, wherein the second horizontal light-blocking part is provided closer to the second surface than the first horizontal light-blocking part.

18. The imaging device according to claim 13, wherein the first horizontal light-blocking part and the second horizontal light-blocking part partially overlap in plan view.

19. The imaging device according to claim 13, wherein
the first vertical light-blocking part and the second vertical light-blocking part respectively include a first protruding part and a second protruding part at the respective intersections opposed to each other, the first protruding part and the second protruding part protruding in the 45-degree oblique direction in a staggered manner, and
a well contact is provided between the first protruding part and the second protruding part, the well contact applying a fixed potential to the semiconductor substrate.

20. An electronic apparatus comprising an imaging device,
the imaging device including
a semiconductor substrate including a first surface and a second surface that are opposed to each other, the semiconductor substrate including a pixel array section in which multiple unit pixels are arranged in an array in a row direction and a column direction,
a photoelectric converter that is provided on side of the second surface of the semiconductor substrate for each of the unit pixels, and generates electric charge corresponding to a light reception amount by photoelectric conversion,
an electric charge holder that is provided on side of the first surface of the semiconductor substrate for each of the unit pixels, and holds the electric charge transferred from the photoelectric converter, and
a first light-blocking section that is provided in the semiconductor substrate and is positioned between the photoelectric converter and the electric charge holder, the first light-blocking section including a first horizontal light-blocking part and a first vertical light-blocking part, the first horizontal light-blocking part extending in an in-plane direction of the semiconductor substrate, the first vertical light-blocking part being orthogonal to the first horizontal light-blocking part, wherein
the first vertical light-blocking part includes a first row light-blocking part and a first column light-blocking part formed along two respective sides, of the unit pixel having a rectangular shape, that are adjacent to each other, the first vertical light-blocking part being provided for each of the unit pixels positioned every other column and in a 45-degree oblique direction, and
the first horizontal light-blocking part has, in plan view, an end at or in vicinity of a position connecting one and another of intersections of the first row light-blocking parts and the first column light-blocking parts that are provided for the respective unit pixels positioned the every other column and in the 45-degree oblique direction.
